(19) United States
(12) Patent Application Publication
(10) Pub. No.: US 2025/0240879 A1
(43) Pub. Date: Jul. 24, 2025

(54) DEVICES, SYSTEMS, AND METHODS FOR MAKING AND USING A FLUID-FILLABLE CIRCUIT

(71) Applicant: Liquid Wire Inc., Portland, OR (US)

(72) Inventors: Jorge E. Carbo, Jr., Portland, OR (US); Mark William Ronay, Portland, OR (US); Michael Jasper Wallans, Portland, OR (US); Sai Srinivas Desabathina, Beaverton, OR (US)

(73) Assignee: Liquid Wire Inc., Portland, OR (US)

(21) Appl. No.: 18/701,414

(22) PCT Filed: Oct. 27, 2022
(86) PCT No.: PCT/US2022/078810

§ 371 Date: Apr. 15, 2024

Related U.S. Application Data
(60) Provisional application No. 63/272,487, filed on Oct. 27, 2021.

(51) Int. Cl. H05K 1/02; H05K 3/46

(52) U.S. Cl. CPC H05K 1/0272; H05K 1/028; H05K 3/4697; H05K 2201/055

(57) ABSTRACT

A fluid-fillable circuit assembly is disclosed herein. The fluid-fillable circuit assembly can include a seal and a layup that includes a substrate layer, a deformable conductor, an encapsulation layer that covers the deformable conductor, and an inner surface. The inner surface and the seal define an internal cavity of the fluid-fillable circuit assembly.

### CROSS-REFERENCE TO RELATED APPLICATIONS

The present application is related to U.S. Provisional Patent Application No. 63/272,487, titled DEVICES, SYSTEMS, AND METHODS FOR MAKING AND USING A FLUID-FILLABLE CIRCUIT, filed Oct. 27, 2021, the disclosure of which is hereby incorporated by reference in its entirety.

### FIELD

The present disclosure is generally related to sustainable, flexible circuits and, more particularly, is directed to flexible circuits that can be either integrated with or attached onto a fluid-fillable bladder such that the flexible circuit can be operable when the bladder is inflated and/or optionally deflated.

### SUMMARY

The following summary is provided to facilitate an understanding of some of the innovative features unique to the aspects disclosed herein and is not intended to be a full description. A full appreciation of the various aspects can be gained by taking the entire specification, claims, and abstract as a whole.

In various aspects, a fluid-fillable circuit assembly is disclosed. The fluid-fillable circuit assembly can include a seal and a layup comprising a substrate layer, a deformable conductor, an encapsulation layer that covers the deformable conductor, and an inner surface. The inner surface and the seal define an internal cavity of the fluid-fillable circuit assembly.

In various aspects, another fluid-fillable circuit assembly is disclosed. The fluid-fillable circuit assembly can include a seal, a first layup, and a second layup. Each of the first layup and the second layup can include a substrate layer, a deformable conductor, an encapsulation layer that covers the deformable conductor, and an inner surface. The inner surface of the first layup, the inner surface of the second layup, and the seal can define an internal cavity of the fluid-fillable circuit assembly.

In various aspects, a method of manufacturing a fluid-fillable circuit assembly is disclosed. The method can include correlating an electrical parameter of the circuit to a structural parameter of the circuit, determining an initial dimension of the deflated circuit based, at least in part, on the correlation and a final structural parameter of the inflated circuit, laminating a substrate layer, a deformable conductor, and an encapsulation layer, to create a layup including the initial dimension, sealing the layup such that an inner surface of the layup and the seal define an internal cavity, and inflating circuit by filling the internal cavity with a fluid, and optionally adjusting the volume and pressure of the fluid within the cavity, until a measured electrical parameter of the circuit correlates to the final structural parameter of the inflated circuit.

These and other features and characteristics of the present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1 illustrates a perspective view of a fluid-fillable circuit, in accordance with one non-limiting aspect of the present disclosure;

FIG. 2 illustrates a cross-sectioned view of the fluid-fillable circuit of FIG. 1, in accordance with at least one non-limiting aspect of the present disclosure;

FIGS. 3A-3D collectively illustrate an assembly of the fluid-fillable circuit of FIG. 1, in accordance with at least one non-limiting aspect of the present disclosure;

FIG. 4 illustrates a perspective view of another inflatable circuit, in accordance with at least one non-limiting aspect of the present disclosure;

FIGS. 5A-5E collectively illustrate an assembly of the fluid-fillable circuit of FIG. 4, in accordance with at least one non-limiting aspect of the present disclosure;

FIG. 6 illustrates a perspective view of another inflatable circuit, in accordance with at least one non-limiting aspect of the present disclosure;

FIGS. 7A-7D collectively illustrate an assembly of the fluid-fillable circuit of FIG. 6, in accordance with at least one non-limiting aspect of the present disclosure;

FIG. 8 illustrates a perspective view of another inflatable circuit, in accordance with at least one non-limiting aspect of the present disclosure;

FIGS. 9A-9D collectively illustrate an assembly of the fluid-fillable circuit of FIG. 8, in accordance with at least one non-limiting aspect of the present disclosure;

FIG. 10 illustrates an assembly of another inflatable circuit featuring an auxiliary device, in accordance with at least one non-limiting aspect of the present disclosure;

FIG. 11, illustrates a perspective view of the assembled inflatable circuit of FIG. 10, in accordance with at least one non-limiting aspect of the present disclosure;

FIG. 12 illustrates a perspective view of another inflatable circuit, in accordance with at least one non-limiting aspect of the present disclosure;

FIGS. 13A and 13B collectively illustrate an assembly of the fluid-fillable circuit of FIG. 10, in accordance with at least one non-limiting aspect of the present disclosure;

FIG. 14 illustrates a flow chart illustrating a method of manufacturing a fluid-fillable circuit, in accordance with at least one non-limiting aspect of the present disclosure;

FIG. 15 illustrates a flow chart illustrating a method of using a fluid-fillable circuit, in accordance with at least one non-limiting aspect of the present disclosure;

FIG. 16 illustrates a flow chart illustrating another method of using a fluid-fillable circuit, in accordance with at least one non-limiting aspect of the present disclosure; and

FIG. 17 illustrates a flow chart of a method of manufacturing a substrate from which a fluid-fillable circuit can be produced, in accordance with at least one non-limiting aspect of the present disclosure.

Corresponding reference characters indicate corresponding parts throughout the several views. The exemplifications set out herein illustrate various aspects of the invention, in one form, and such exemplifications are not to be construed as limiting the scope of the invention in any manner.

### DETAILED DESCRIPTION

Numerous specific details are set forth to provide a thorough understanding of the overall structure, function, manufacture, and use of the aspects as described in the disclosure and illustrated in the accompanying drawings. Well-known operations, components, and elements have not been described in detail so as not to obscure the aspects described in the specification. The reader will understand that the aspects described and illustrated herein are non-limiting examples, and thus it can be appreciated that the specific structural and functional details disclosed herein may be representative and illustrative. Variations and changes thereto may be made without departing from the scope of the claims. Furthermore, it is to be understood that such terms as “forward”, “rearward”, “left”, “right”, “upwardly”, “downwardly”, and the like are words of convenience and are not to be construed as limiting terms. Furthermore, it is to be understood that such terms as “forward”, “rearward”, “left”, “right”, “upwardly”, “downwardly”, and the like are words of convenience and are not to be construed as limiting terms.

In the following description, like reference characters designate like or corresponding parts throughout the several views of the drawings. Also in the following description, it is to be understood that such terms as “forward”, “rearward”, “left”, “right”, “upwardly”, “downwardly”, and the like are words of convenience and are not to be construed as limiting terms.

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves any and all copyrights disclosed herein.

The devices, systems, and methods disclosed in U.S. Provisional Patent Application No. 63/154,665, titled HIGHLY SUSTAINABLE CIRCUITS AND METHODS FOR MAKING THEM, filed Feb. 26, 2021, the disclosure of which is hereby incorporated by reference in its entirety, U.S. Provisional Patent Application No. 63/243,206, titled SUSTAINABLE INFLATABLE CIRCUITS AND METHODS FOR MAKING THEM, filed Sep. 13, 2021, the disclosure of which is hereby incorporated by reference in its entirety, and U.S. Provisional Patent Application No. 63/366,778, titled DEVICES, SYSTEMS, AND METHODS FOR MAKING AND USING PARTIALLY FLUID-FILLED; CIRCUITS, filed Jun. 22, 2022, the disclosure of which is hereby incorporated by reference in its entirety, are relevant to the subject matter herein.

Electronic circuits that are flexible and deformable have emerged as a means of innovating conventional electronics and introducing electronics into new products and applications. However, it would be beneficial for flexible electronic circuits to form a sealed, internal cavity, which can be filled with a fluid. Such circuits could expand and contract in accordance with the selective insertion and/or removal of the fluid from the internal cavity, and/or external and internal physical stimuli applied to the circuit. Moreover, changes in circuit geometry may lead to a subsequent change in electrical parameters generated across the fluid-fillable circuit, which could be used to characterize a structural parameter or condition of the circuit, as desired. Indeed, inflatable circuits may provide numerous benefits for airbags, fluid-filled bladders, and/or cushions, which could be calibrated, monitored, and even controlled based on measured electrical parameters. Accordingly, there is a need for devices, systems, and methods for making and using a fluid-fillable circuit.

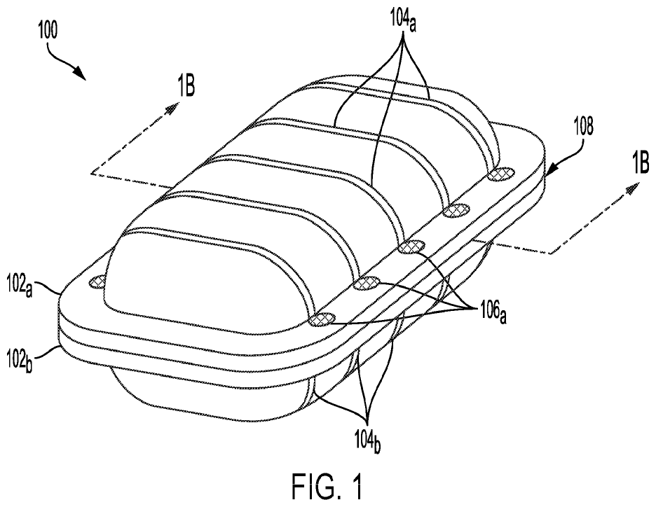

Referring now to FIG. 1, a perspective view of a fluid-fillable circuit 100 is depicted in accordance with at least one non-limiting aspect of the present disclosure. According to the non-limiting aspect of FIG. 1, the fluid-fillable circuit 100 can include a first layup 102ₐ, and a second layup 102_{b}. The first layup 102ₐ can include a first plurality of traces 104ₐ and the second layup 102_{b} can include a second plurality of traces 104. The first layup 102ₐ of FIG. 1 can be placed on top of—and mechanically coupled to—the second layup 102_{b} such that selected features—for example, the first plurality of traces 104ₐ and the second plurality of traces 104_{b}, are aligned. For example, each trace 104ₐ of the first plurality of traces 104ₐ can be electrically coupled to a corresponding trace 104_{b} of the second plurality of traces 104_{b} via a plurality of electrical vias 106ₐ and 106_{b} (not shown) positioned at a mechanical interface of the first layup 102ₐ and the second layup 102_{b}. However, in other non-limiting aspects, the first layup 102ₐ can be mechanically coupled, fused, or otherwise integrated to the second layup 102_{b} and a single plurality of traces can be deposited and/or coupled to both the first layup 102ₐ and the second layup 102_{b}, such that each trace of the plurality traverses the entire perimeter collectively defined by the first layup 102ₐ and the second layup 102_{b}.

According to the non-limiting aspect of FIG. 1, the vias 106 of the first layup 102ₐ can be dimensioned and positioned such that they substantially correspond to and align with the vias (not shown) of the second layup 102_{b}. However, in other non-limiting aspects, vias 106 of the first layup 102ₐ can be alternately configured relative to the vias 106 of the second layup 102_{b}. For example, the vias 106 of the first layup 102ₐ can be larger than the vias 106 of the second layup 102_{b} to account for tolerances and/or misalignment. Alternatively and/or additionally, the vias 106 of the first layup 102ₐ may be intentionally misaligned relative to the vias 106 of the second layup 102_{b}

Still referring to FIG. 1, the first layup 102ₐ and the second layup 102_{b} of FIG. 1 can be configured such that either the first layup 102ₐ or the second layup 102_{b} can be positioned on top of the other. However, in other non-limiting aspects, either the first layup 102ₐ or the second layup 102ₐ can be specifically configured as a top portion or a bottom portion of the fluid-fillable circuit 100. For example, it may be preferable for a top portion or a bottom portion of the fluid-fillable circuit 100 to have specifically configured dimensions, mechanical features, and/or electrical features. As such, either the first layup 102ₐ or the second layup 102_{b} can be configured to include such features, rendering them exclusively suitable for placement on the top portion or a bottom portion of the fluid-fillable circuit 100. Some non-limiting examples of “other features” that can be added to the first layup 102ₐ or the second layup 102_{b} include electronic components, portions of the trace pattern, trace breaks with vias at trace endpoints, and/or a predetermined dimension of the first layup 102ₐ or the second layup 102_{b} when the fluid-fillable circuit 100 is, e.g., either inflated or deflated, amongst others. Alternatively and/or additionally, the first layup 102ₐ of FIG. 1 can be arranged relative to the second layup 102_{b} such that other features of the first layup 102ₐ are preferably aligned with other features of the second layup 102_{b}.

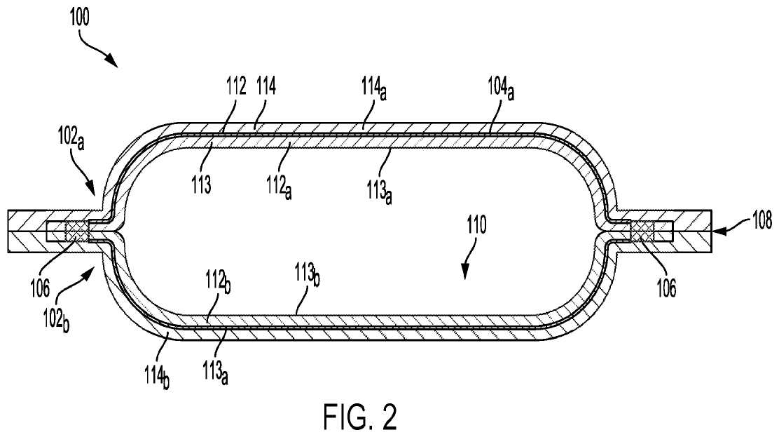

As used herein, the term “inflate” shall include the introduction of any foreign substance into an internal cavity 110 (FIG. 2) defined by the first and second layups 102ₐ, 102_{b}. For example, as used herein, “inflation” can include the introduction of a compressible fluid, a non-compressible fluid, a foam, and/or particles, amongst other media, into an internal cavity 110 (FIG. 2) of the circuit 100. Likewise, the term “deflate” shall include the removal of any foreign substance from the internal cavity 110 (FIG. 2) defined by the first and second layups 102ₐ, 102_{b}. However, according to some non-limiting aspects, a “deflated” condition of the circuit can include an initial state after forming the bladder and/or a state after fluid has been released from the bladder.

According to the non-limiting aspect of FIG. 1, the first layup 102ₐ and the second layup 102_{b} can be composed of flexible and stretchable materials, such as those disclosed by U.S. patent application Ser. No. 16/548,379 titled STRUCTURES WITH DEFORMABLE CONDUCTORS, which was filed on Aug. 22, 2019 and granted as U.S. Pat. No. 11,088,063 on Aug. 10, 2021, the disclosure of which is hereby incorporated by reference in its entirety. Specifically, the first layup 102ₐ and the second layup 102_{b} can be fabricated from a flexible or stretchable material such as a natural rubber, a synthetic rubber, a flexible plastic, a silicone based material (e.g., polydimethylsiloxane (“PDMS”), thermoplastic polyurethane (“TPU”), ethylene propylene diene terpolymer (“EPDM”), neoprene, polyethylene terephthalate (“PET”), etc.), a flexible composite material, and/or a naturally flexible materials, such as a leather, for example. For example, the first layup 102ₐ and/or the second layup 102_{b} can be fabricated from a resilient, albeit stretchable TPU, such as Lubrizol® Estane® 58000 series (e.g., 58238), amongst others. Alternatively, the first layup 102ₐ and/or the second layup 102_{b} can be formed from a flexible, though comparatively more rigid material, such as Lubrizol® Estane® S375D, amongst others.

Since each trace 104ₐ of the first plurality of traces 104ₐ can be electrically coupled to a corresponding trace 104_{b} of the second plurality of traces 104_{b} via the plurality of electrical vias 106ₐ and 106_{b}, according to some non-limiting aspects, it may be preferable to fill the vias 106ₐ, 106_{b} with a deformable conductor configured to convey electrical energy between corresponding traces 104ₐ, 104_{b}. Such a deformable conductor is represented via the cross-hatching in FIGS. 1-3D. The deformable conductor placed in the vias 106ₐ, 106_{b} can be the same as, or similar to, the deformable conductors used for the traces 104ₐ, 104_{b}. Alternately, the deformable conductor placed in the vias 106ₐ, 106_{b} can be different than the deformable conductors used for the traces 104ₐ, 104_{b}. However, the use of cross-hatching is merely illustrative and the particular nature and/or absence of cross-hatching in any of the figures shall not be construed as limiting to the deformable conductor and/or the vias 106ₐ, 106_{b}, themselves. According to other non-limiting aspects, it shall be appreciated that the vias 106ₐ, 106_{b} can be alternately configured to convey electrical energy between corresponding traces 104ₐ, 104_{b} of the circuit 100.

As used herein, the term “deformable conductor” shall include but shall not be limited to, any conductor that is in a fluid state, or any conductor that can transition into a fluid state when an external stimulus (e.g. a strain, etc.) is applied to either the conductor or a structure surrounding the conductor, wherein the conductor is also capable of returning to a pre-stimulus state. Alternatively and/or additionally, a “deformable conductor” can include an elastic property greater than an elastic property of its surrounding structure, such that the conductor will not plastically deform before the surrounding structure plastically deforms. In other words, a “deformable conductor,” as used herein, shall include a rigidity that does not preclude the fluid-fillable circuits disclosed herein from undergoing the requisite transition between a first (e.g., deflated) state to a second (e.g., inflated) state while preserving electrical communication throughout the circuit in either the first or second state. In this regard, a “deformable conductor” is distinguished from conventional conductors, such as copper wires, which would prevent the transition between the first and second states, or whose rigidity might break the electrical communication throughout the circuit during said transitions.

Similarly, the traces 104ₐ, 104_{b} of the circuit 100 of FIG. 1 can include a deformable, conductive material, such as those disclosed in International Patent Application No. PCT/US2017/019762 titled LIQUID WIRE, which was filed on Feb. 27, 2017 and published on Sep. 8, 2017 as International Patent Publication No. WO2017/151523A1, the disclosure of which is hereby incorporated by reference in its entirety. For example, each trace 104ₐ, 104_{b} can include a variety of forms, such as a liquid, a paste, a gel, and/or a powder, amongst others that would enable the traces 104ₐ, 104_{b} to have a deformable (e.g., soft, flexible, stretchable, bendable, elastic, flowable viscoelastic, Newtonian, non-Newtonian, etc.) quality. According to some non-limiting aspects, the deformable, conductive materials can include an electroactive material, such as a deformable conductors produced from a conductive gel (e.g., a gallium indium alloy). The conductive gel can have a shear thinning composition and, according to some non-limiting aspects, can include a mixture of materials in a desired ratio. For example, according to one preferable non-limiting aspect, the conductive gel can include a weight percentage of a eutectic gallium alloy between 59.9% and 99.9% and a weight percentage of a gallium oxide between 0.1% and about 2.0%. Of course, the present disclosure contemplates other non-limiting aspects, featuring traces 104ₐ, 104_{b} of varying forms and/or compositions to achieve the benefits disclosed herein.

In some aspects, a viscosity of the deformable conductive material may, when under high shear (e.g., in motion), be in a range of about 10 Pascal seconds (Pas) and 500 Pa*s, such as a range of 50 Pa*s and 300 Pa*s, and/or may be about 50 Pa*s, about 60 Pa*s, about 70 Pa*s, about 80 Pa*s, about 90 Pa*s, about 100 Pa*s, about 110 Pa*s, about 120 Pa*s, about 130 Pa*s, about 140 Pa*s, about 150 Pa*s, about 160 Pa*s, about 170 Pa*s, about 180 Pa*s, about 190 Pa*s, or about 200 Pa*s. In some aspects, a viscosity of the deformable conductive material may, when under low shear (e.g., at rest), be in a range of 100,000 Pa*s and 40,000,000 Pa*s, such as a range of 1,000,000 Pa*s and 40,000,000 Pa*s, and/or may be about 10,000,000 Pa*s, about 20,000,000 Pa*s, about 30,000,000 Pa*s, or about 40,000,000 Pa*s.

In further reference to FIG. 1, the first layup 102ₐ can be configured to mechanically interface the second layup 102_{b} such that a seal 108 can be formed between the first layup 102ₐ and the second layup 102_{b}. The seal 108 can be formed via a process configured to attach an outer perimeter of the first layup 102ₐ to an outer perimeter of the second layup 102_{b}, including any known process that uses heat, pressure, radio-frequency energy, and/or additional materials for attachment (e.g., welding, soldering, fusing, stitching, adhesives, etc.). According to some non-limiting aspects, the seal 108 can be formed using a radio-frequency weld procedure, an adhesive (e.g., a thermoset, a thermoplastic adhesive film, etc.), or a thermos-sensitive mask coating (e.g., silicone) that can be applied to regions of the layups 102ₐ, 102_{b} that will not be sealed (e.g., inner surfaces of the cavity). As such, an inner surface 113ₐ (FIG. 2) of the first layup 102ₐ and an inner surface 113_{b} (FIG. 2) of the second layup 102_{b} can collectively define an internal cavity 110 (FIG. 2) configured to accommodate a fluid (e.g., compressible, non-compressible). Because the first layup 102ₐ, the second layup 102_{b}, and the traces 104ₐ, 104_{b} of the circuit 100 may be fabricated from flexible materials, the circuit 100 of FIG. 1 can stretch as the fluid is introduced to the internal cavity. In other words, the circuit 100 of FIG. 1 can be selectively inflated and deflated as the fluid is introduced and/or removed from the internal cavity. According to the non-limiting aspect of FIG. 1, the fluid-fillable circuit 100 is depicted in an inflated condition, meaning the internal cavity defined by an inner surface 113ₐ (FIG. 2) of the first layup 102ₐ and an inner surface 113_{b} (FIG. 2) of the second layup 102_{b} is accommodating a fluid.

Still referring to FIG. 1, the circuit 100 can be inflated using various known methods of inflation, such as the method described in U.S. patent application Ser. No. 11/107,354 titled FLUID-FILLED BLADDER FOR FOOTWEAR AND OTHER APPLICATIONS, which was filed on Apr. 14, 2004 and granted on Jul. 22, 2009 as U.S. Pat. No. 7,401,369, the disclosure of which is hereby incorporated by reference in its entirety. For example, the first layup 102ₐ and the second layup 102_{b} of FIG. 1 can include a multi-layer construction, and at least a portion of the first layup 102ₐ and the second layup 102_{b} can be fabricated from a microlayer membrane, such as those described in U.S. patent application Ser. No. 11/107,354. However, according to other non-limiting aspects, a valve assembly can be mechanically coupled to the circuit 100 of FIG. 1, and fluid can be selectively introduced and/or removed from the internal cavity via the valve assembly. For example, according to some non-limiting aspects, the circuit 100 can include a valve assembly similar to those disclosed in U.S. Pat. No. 5,257,470, titled SHOE BLADDER SYSTEM, and issued on Nov. 2, 1993, the disclosure of which is hereby incorporated by reference in its entirety.

Referring now to FIG. 2, a cross-sectioned view of either the fluid-fillable circuit 100 of FIG. 1 is depicted in accordance with at least one non-limiting aspect of the present disclosure. The cross-section of FIG. 2 was taken about line 1B in FIG. 1. In FIG. 2, the multi-layer nature of the first layup 102ₐ and the second layup 102_{b} becomes apparent. For example, according to the non-limiting aspect of FIG. 2, the layups 102ₐ, 1012_{b} can include a two-layer 112, 114 construction. Specifically, each of the first layup 102ₐ and the second layup 102_{b} of the fluid-fillable circuit 100 of FIG. 1 can include a substrate layer 112ₐ, 112_{b} and an encapsulation layer 114ₐ, 114_{b}. However, according to other non-limiting aspects, the layups 102ₐ, 1012_{b} can include three or more layers, including a stencil layer configured to accommodate the traces 104_{a,b} (FIG. 1), as described in U.S. patent application Ser. No. 16/548,379 titled STRUCTURES WITH DEFORMABLE CONDUCTORS, which was filed on Aug. 22, 2019 and granted as U.S. Pat. No. 11,088,063 on Aug. 10, 2021, the disclosure of which is hereby incorporated by reference in its entirety. In still other non-limiting aspects, the layups 102ₐ, 102_{b} can include a single layer configured to accommodate the traces 104ₐ,, 104_{b}.

Alternately and/or additionally, the flexible structures described in U.S. Provisional Patent Application No. 63/261,266, titled STRETCHABLE AND FLEXIBLE METAL FILM STRUCTURES, filed Sep. 21, 2021, the disclosure of which is hereby incorporated by reference in its entirety, can be used to fabricate one or more layers of the layups 102ₐ, 102_{b}, as depicted in FIG. 2. For example, the layups 102ₐ, 102_{b} can be produced from one or more layers including a B-stage resin film, a C-stage resin film, an adhesive, a TPU, and/or a silicone material, amongst others.

According to the non-limiting aspect of FIG. 2, the substrate layers 112ₐ, 112_{b} of the first and second layups 102ₐ, 102_{b} can include one or more features, such as a contact point configured to mechanically and/or electrically engage with an electronic component mounted to the layups 102ₐ, 102_{b} and/or one or more of the traces 104_{a,b}. The traces 104_{a,b} and, more specifically, a deformable conductor from which the traces 104_{a,b} are composed, can be deposited either on or embedded within a portion of the substrate layers 112ₐ, 112_{b}. Collectively, the encapsulation layers 114ₐ, 114_{b} can contain and protect the fluid-fillable circuit 100, including any traces 106, electronic components, and/or contact points coupled to the substrate layers 112ₐ, 112_{b}. The encapsulation layers 114ₐ, 114_{b} can also fill any spaces between the components and the substrate layers 112ₐ, 112_{b}. For example the encapsulation layer 114 can be formed from materials suitable for the encapsulation of electronics, including silicone-based materials such as PDMS, urethanes, epoxies, polyesters, polyamides, and/or varnishes, amongst other materials capable of providing a sufficient protective coating and/or assisting in holding the fluid-fillable circuit 100 assembly together.

According to some non-limiting aspects, the circuit 100 of FIG. 2 can be assembled in accordance with the design for manufacture techniques disclosed in U.S. Provisional Patent Application No. 63/261,266, titled STRETCHABLE AND FLEXIBLE METAL FILM STRUCTURES, filed Sep. 21, 2021, the disclosure of which is hereby incorporated by reference in its entirety. For example, the traces 104ₐ, 104_{b}, vias 106ₐ, 106_{b}, and contacts (not shown) may be particularly sized and spaced, the ampacity of traces 104ₐ, 104_{b} may be configured, and the various features of the layups 102ₐ, 102_{b} may be attached in accordance with the techniques described for non-inflatable laminate structures, as disclosed therein.

For example, the substrate layers 112ₐ, 112_{b} and encapsulation layers 114ₐ, 114_{b} can be configured similar to the substrate layers and encapsulants described in U.S. patent application Ser. No. 16/548,379 titled STRUCTURES WITH DEFORMABLE CONDUCTORS, which was filed on Aug. 22, 2019 and granted as U.S. Pat. No. 11,088,063 on Aug. 10, 2021, the disclosure of which is hereby incorporated by reference in its entirety. Alternatively and/or additionally, the substrate layers 112ₐ, 112_{b} and encapsulation layers 114ₐ, 114_{b} can be formed from a microlayer membrane that facilitates inflation of the fluid-fillable circuit 100 with a compressible fluid, such as the membranes disclosed in U.S. patent application Ser. No. 11/107,354 titled FLUID-FILLED BLADDER FOR FOOTWEAR AND OTHER APPLICATIONS, which was filed on Apr. 14, 2004 and granted on Jul. 22, 2009 as U.S. Pat. No. 7,401,369, the disclosure of which is hereby incorporated by reference in its entirety.

As depicted in FIG. 2, one or more vias 106 can be configured to traverse at least a portion of the substrate layers 112ₐ, 112_{b} and/or the encapsulation layers 114ₐ, 114_{b} of the layups 102ₐ, 102_{b}, creating an electrical conduit by which a desired electrical connection between electrical features of the first and second layups 102ₐ, 102_{b} can be established. For example, according to the non-limiting aspect of FIG. 2, the vias 106 can be formed through the substrate layers 112ₐ, 112_{b} such that the traces 104ₐ, 104_{b} of the first and second layups 102ₐ, 102_{b} are electrically coupled. However, vias 106 can similarly be configured to electrically couple electronic components and/or contact points coupled to each of the first and second layups 102ₐ, 102_{b}. According to other non-limiting aspects, the top layup 102ₐ and the bottom layup 102_{b} can each be independently encapsulated, such that each surface of the substrate layer 112ₐ of the top layup 102ₐ and the substrate layer 112_{b} of the bottom layup 102_{b} is covered by the encapsulation layer 114ₐ of the top layup 102ₐ and the encapsulation layer 114_{b} of the bottom layup 102_{b}, respectively. In such aspects, one or more vias 106 may traverse the encapsulation layers 114ₐ, 114_{b}, such that a trace 106ₐ on the substrate layer 112ₐ of the top layup 112ₐ is electrically coupled to a trace 106_{b} on the substrate layer 112_{b} of the bottom layup 102_{b}.

According to other non-limiting aspects, the layups 102ₐ, 102_{b} can further include a stencil configured to accommodate the traces 104ₐ, 104_{b}, such as those described in U.S. patent application Ser. No. 16/548,379 titled STRUCTURES WITH DEFORMABLE CONDUCTORS, which was filed on Aug. 22, 2019 and granted as U.S. Pat. No. 11,088,063 on Aug. 10, 2021, the disclosure of which is hereby incorporated by reference in its entirety. For example, a stencil can be particularly constructed to define paths for one or more of the traces 104ₐ, 104_{b} that traverse the fluid-fillable circuit 100 in accordance with a schematic for the fluid-fillable circuit 100. The paths defined by such stencils can accommodate the deformable conductor, which can be deposited within the stencil and covered by the encapsulation layers 114ₐ, 114_{b} such that the stencil and deformable conductors, which define the traces 104ₐ, 104_{b}, are bound between the substrate layers 112ₐ, 112_{b} and encapsulation layers 114ₐ, 114_{b}. Optionally, a pattern of traces may be formed in or on the substrate layers 112ₐ, 112_{b}, e.g., by laser ablation, thermoforming, molding, or other suitable additive or subtractive methods prior to depositing the deformable conductor on or in the substrate layer.

Still referring to FIG. 2, the internal cavity 110 collectively defined by the inner surface 113ₐ of the first layup 102ₐ, the inner surface 113_{b} of the second layup 102_{b}, and the seal 108 is illustrated in accordance with at least one non-limiting aspect of the present disclosure. As noted in reference to FIG. 1, the internal cavity 110 can accommodate a fluid (e.g., octafluoropropane, nitrogen, air, etc.), which can be compressible or non-compressible. The fluid can be pressurized as required by the particular application. For example, it may be desirable to pressurize the internal cavity 110 to a gauge pressure within a range of 1-35 pounds-per-square-inch (“PSI”). According to some non-limiting aspects, the internal cavity 110 may be configured to accommodate a pressure of about 20 PSI in an inflated condition. In other words, the fluid-fillable circuit 100—and more specifically, the internal cavity 110 collectively defined by the inner surface 113ₐ of the first layup 102ₐ, the inner surface 113_{b} of the second layup 102_{b}, and the seal 108—can be particularly configured to accommodate an internal fluid pressure that is slightly above ambient, or relatively high. In still other non-limiting aspects, the fluid-fillable circuit 100 can be similarly configured to bladders made using aspects described in U.S. patent application Ser. No. 11/107,354 titled FLUID-FILLED BLADDER FOR FOOTWEAR AND OTHER APPLICATIONS, which was filed on Apr. 14, 2004 and granted on Jul. 22, 2009 as U.S. Pat. No. 7,401,369, the disclosure of which is hereby incorporated by reference in its entirety.

As depicted in FIG. 2, the fluid-fillable circuit 100 can be geometrically configured such that the internal cavity 110 includes a stadium-like (e.g., substantially rectangular, with rounded edges) cross section. However, the fluid-fillable circuit 100 can be alternately configured to have a number of different geometries, depending on user preference and/or intended application. For example, according to some non-limiting aspects, the fluid-fillable circuit 100 can be circular, spherical, hexagonal, rectangular, triangular or irregularly shaped. Such configurations may not be apparent from the cross-section of the fluid-fillable circuit 100, but evident when the fluid-fillable circuit 100 is viewed from above. In still other non-limiting aspects, the fluid-fillable circuit 100 can have an arbitrary or abstract geometry, such as the bladders described in U.S. patent application Ser. No. 11/107,354 titled FLUID-FILLED BLADDER FOR FOOTWEAR AND OTHER APPLICATIONS, which was filed on Apr. 14, 2004 and granted on Jul. 22, 2009 as U.S. Pat. No. 7,401,369, the disclosure of which is hereby incorporated by reference in its entirety. Such bladders are generally hexagonal but include one or more indents that abstract the geometry. According to other non-limiting aspects, the fluid-fillable circuit 100 can be one of a plurality of inflatable circuits 100, wherein the plurality of inflatable circuits 100 are arranged in a tessellated pattern. In other words, each fluid fillable circuit 100 of the plurality can have a substantially similar shape and can be arranged such that the plurality of inflatable circuits 100 collectively cover an area without a significant gap and/or overlap.

Alternately and/or additionally, a fluid-fillable circuit 100 may be formed such that the circuit 100 is substantially flat in an uninflated configuration but can be molded to have varied three-dimensional surface topographies and shapes with varying degrees of complexity and contour. According to such aspects, three-dimensional forming can occur at the time of inflation, for example by thermoforming in a mold cavity having the desired final three-dimensional shape using, for example, inflation pressure. According to other non-limiting aspects, a fluid-fillable circuit 100 or system may be similarly molded in a secondary operation post-inflation, for example by thermal compression-molding in a mold cavity having the desired final 3-dimensional shape. It shall be appreciated that such methods of formation can be employed to form any of the circuits disclosed herein.

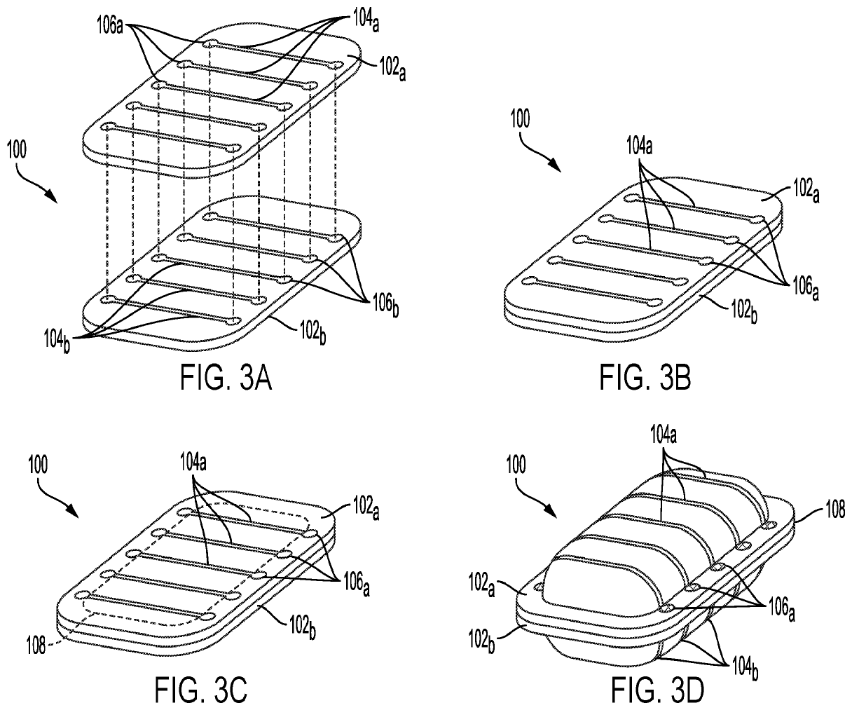

Referring now to FIGS. 3A-3D, several assembly diagrams of the fluid-fillable circuit 100 of FIG. 1 are depicted in accordance with at least one non-limiting aspect of the present disclosure. Specifically, FIGS. 3A-3D illustrate how the first layup 102ₐ can include features (e.g., traces 104ₐ, vias 106ₐ, etc.) that can be particularly dimensioned and positioned on the first layup 102ₐ, such that they correspond to features (e.g., traces 104_{b}, vias 106_{b}, etc.) on the second layup 102_{b}. For example, as depicted in FIG. 3A, the traces 104ₐ and vias 106ₐ of the first layup 102ₐ are dimensioned and positioned on the first layup 102ₐ such that they align with and electrically coupled to a corresponding trace 104_{b} or via 106_{b} on the second layup 102_{b}. This alignments is depicted in FIG. 3B, where the first layup 102ₐ is positioned above the second layup 102_{b}, such that corresponding features of the first and second layup 102ₐ, 102_{b} can be electrically coupled.

According to the non-limiting aspect of FIG. 3B, the first layup 102ₐ can have a design that is substantially similar (e.g., a one-for-one match) to a design of the second layup 102_{b}. In other words, the features of the first layup 102ₐ can be similarly dimensioned and positioned relative to corresponding features of the second layup 102_{b}. However, according to other non-limiting aspects, the first layup 102ₐ can be alternately designed relative to the second layup 102_{b}. Some or all of the features (e.g., traces 104ₐ, vias 106ₐ, etc.) of the first layup 102ₐ can be alternately dimensioned and/or positioned relative to corresponding features on the second layup 102_{b}. For example, it might be desirable to account for manufacturing tolerances and/or alignment issues by dimensioning one or more of the vias 106ₐ of the first layup 102ₐ with a larger diameter relative to a diameter of a corresponding via 106_{b} of the second layup 102_{b}. Alternately and/or additionally, one or more of the vias 106ₐ of the first layup 102ₐ can be positioned such that it is staggered relative to a corresponding via 106_{b} of the second layup 102_{b}. Such design modifications can ensure a proper electrical connection between traces 104ₐ, 104_{b} can be achieved. In still other non-limiting aspects, the features of the layups 102ₐ, 102_{b} have different geometric configurations (e.g., triangular, rectangular, hexagonal, three-dimensional, etc.).

According to still other non-limiting aspects, the layups 102ₐ, 102_{b} of FIGS. 3A-3D can have differing sizes and/or shapes. For example, according to some non-limiting aspects, the second layup 102_{b} can have a larger overall surface area relative to the first layup 102ₐ, or vice-versa, such that only a portion of the circuit 100 is inflatable and some features (e.g., traces 104_{b}, vias 106_{b}, etc.) of the second layup 102_{b} are do not correspond to the shape of the internal cavity 110 (FIG. 2). Layups 102ₐ, 102_{b} of differing sizes and/or shapes can be useful for aspects in which the fluid-fillable circuit 100 is integrated into an external structure or housing, wherein only a portion of the structure or housing is intended to support inflation of the circuit 100, but where a stretchable, bendable, or otherwise flexible circuit is integrated to other portions.

Additionally and/or alternately, such non-inflated circuit portions can be in electrical communication with inflated portions of the fluid-fillable circuit 100. Furthermore, both the first and second layups 102ₐ, 102_{b} can have portions that do not correspond to the shape (e.g., when viewed in plan, for example) of the internal cavity 110, and in some non-limiting aspects, such portions may overlap and/or substantially overlay one another. According to still other non-limiting aspects overlapping or overlaid portions can be bonded or otherwise unitized to one another. In all such examples where at least one uninflated portion does not correspond to the shape of the internal cavity is provided in either and/or both of the first and second layups 102ₐ, 102_{b}, such uninflated portions may extend from a surface of the inflated portion of the circuit 100 and/or the seal 108, itself. Such uninflated portions may extend into the cavity 110 so as to be contained within the internal volume of the inflated circuit, or they may extend away from the inflated portion such that they are external to the volume of the cavity 100. It shall be appreciated that similar uninflated portions can be implemented in any of the circuits disclosed herein.

As such, it shall be appreciated that the geometric configuration of the layups 102ₐ, 102_{b} of FIGS. 3A-3D, including the geometric configuration of their respective features (e.g., traces 104ₐ, 104_{b}, vias 106ₐ, 106_{b}, etc.) are not intended to be limiting, and that the present disclosure contemplates numerous aspects wherein the geometric configuration of the layups 102ₐ, 102_{b} are attenuated to achieve a desired mechanical and/or electrical integration of the fluid-fillable circuit 100.

According to FIG. 3C, once the layups 102ₐ, 102_{b} are aligned, as depicted in FIG. 3B, features (e.g., traces 104ₐ, vias 106ₐ, etc.) of the first layup 102ₐ can be electrically coupled to corresponding features (e.g., traces 104_{b}, vias 106_{b}, etc.) of the second layup 102_{b}. For example, in FIG. 3C, the substrate layer 112ₐ of the top layup 102ₐ can be brought into contact with or otherwise positioned adjacent the substrate layer 112_{b} of the bottom layup 102_{b}, such that the vias align 106ₐ, 106_{b} and corresponding traces 104ₐ of the top layup 102ₐ are in electrical communication with the traces 104_{b} of the bottom layup 102_{b}. It shall be appreciated that in embodiments having layups that are mirror images of one another, such as the ones depicted here, it may be desirable that corresponding features such as vias are formed in the same layer of both layups (e.g., the encapsulation layers, or the substrate layers) for ease of manufacturing and inventory control. However, in embodiments (not shown here) where the various layups are not mirror images of one another, it may be preferable but not necessary for corresponding features such as vias to be formed in different layers of each layup (e.g., the encapsulation layer of one and the substrate layer of the other). A region of the first layup 102ₐ can be subsequently bonded or unitized to a corresponding region of the second layup 102_{b} by any known process of attachment (e.g., welding, soldering, fusing, stitching, adhesives, etc.), thereby creating the seal 108 of the internal cavity 110 (FIG. 2). According to the non-limiting aspect of FIG. 3C, the corresponding regions—and thus, the sealed portion—of the first and second layups 102ₐ, 102_{b} can be located on the perimeter of the first and second layups 102ₐ, 102_{b}, and can include any overlapping vias 106ₐ, 106_{b} positioned in those regions. As such, the first and second layups 102ₐ, 102_{b} can be securely fastened, and the traces 104ₐ, 104_{b} reliably held in electrical communication by the aligned vias 106ₐ, 106_{b}. Accordingly, the fluid-fillable circuit 100 can be assembled such that a portion of the inner surface 113ₐ (FIG. 2) of the first layup 102ₐ is not adhered to a portion of the inner surface 113_{b} (FIG. 2) of the second layup 102_{b} and thus, the portion of the inner surface 113ₐ (FIG. 2) can be separated from the portion of the inner surface 113_{b} (FIG. 2). Such separation can be caused by a fluid inserted into the internal cavity 110 (FIG. 2) and contained within the internal cavity 110 (FIG. 2) via the seal 108. Thus, due to the deformable nature of the substrate layers 112ₐ, 112_{b} (FIG. 2), encapsulation layers 114ₐ, 114_{b} (FIG. 2), and traces 104ₐ, 104_{b}, the circuit 100 can be inflated, as illustrated in FIG. 3D. It may be appreciated that after sealing, portions of the seal 108 may not be structurally or electrically necessary and may be trimmed from the fluid-fillable circuit 100 for aesthetic or other reasons and that this is true for all of the circuits disclosed herein.

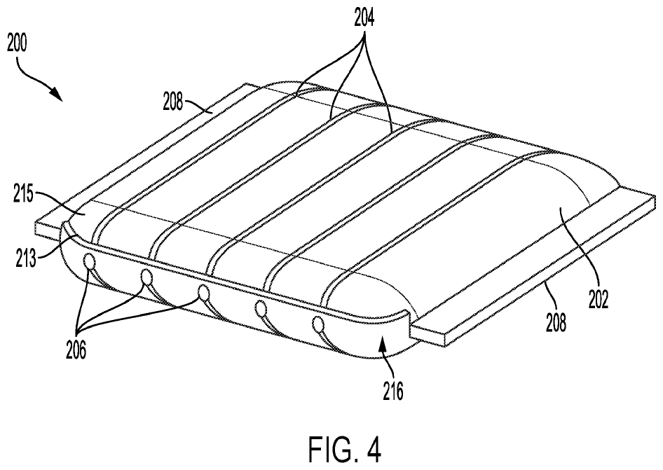

Referring now to FIG. 4, a perspective view of another inflatable circuit 200 is depicted in accordance with at least one non-limiting aspect of the present disclosure. According to the non-limiting aspect of FIG. 4, the fluid-fillable circuit 200 can include a single layup 202 with a plurality of traces 204. The single layup 202 of FIG. 4 can include a multi-layer construction, similar to the layups 102ₐ, 102_{b} of FIG. 2. Likewise, each trace 204 of the plurality can be constructed from a deformable conductive material deposited on or within a substrate layer and encapsulated. According to some non-limiting aspects, the layup 202 can further include a stencil, which can define paths for the traces 204 in which the deformable conductor can be deposited and contained.

According to the non-limiting aspect of FIG. 4, the layup 202 can be folded or rolled such that a first portion of the layup 202 overlaps with a corresponding, second portion of the layup 202. The layup 202 can be geometrically configured such that, when the layup 202 is folded, one or more vias 206 positioned on the first portion of the layup 202 can be aligned and placed in electrical communication with a corresponding via 206 the second portion of the layup 202. The alignment of the vias 206 in this embodiment results in a desired alignment of traces 204, which traverse between a via 204 on the first portion and a via 206 on the second portion. In some examples, traces 204 may have patterns that do not overlay as shown. Once the vias 206 and traces 204 are aligned, the first portion of the layup 202 can be bonded to the second portion of the layup 202 by any known process of attachment (e.g., welding, soldering, fusing, stitching, adhesives, etc.), thereby creating a sealed lap joint 216 between an inner surface 213 and an outer surface 215 of the layup 202. According to the non-limiting aspect where the single layup 202 has a construction similar to the layups 102ₐ, 102_{b} of FIG. 2, an encapsulation layer of the layup 202 can overlap and be bonded to a substrate layer of the layup 202 to form the lap joint 216. The creation of the lap joint 216 may result in non-overlapping, side portions of the layup 202, which may be bonded via any known process of attachment (e.g., welding, soldering, fusing, stitching, adhesives, etc.), thereby creating a seal 208 on either side of the fluid-fillable circuit 200. The seal 208 can be formed in the same bonding operation as the lap joint 216 or, alternately, via a separate bonding operation. According to some non-limiting aspects, the layup 202 can be alternately configured such that the otherwise additional lap joints can be formed on either side of the fluid-fillable circuit 200, such that the additional lap joints can be used in lieu of the seals 208 of FIG. 4.

Similar to the multi-layup circuit 100 of FIG. 2, when assembled, the circuit 200 of FIG. 4 can define an internal cavity configured to accommodate and contain a fluid. Specifically, the internal cavity can be defined by the inner surface 213, the lap joint 216, and the seal 208 of the layup 202. Although the circuit 200 of FIG. 4 defines an internal cavity having a stadium-like cross section, the fluid-fillable circuit 200 can be alternately configured to have a number of different geometries, depending on user preference and/or intended application. For example, according to some non-limiting aspects, the fluid-fillable circuit 200 can be circular, hexagonal, rectangular, or triangular. Similar to the circuit 100 of FIG. 1, according to other non-limiting aspects, the circuit 200 of FIG. 4 is one of a tessellated plurality. Regardless of its particular geometric configuration, the circuit 200 of FIG. 4 can be inflated by inserting a fluid into the internal cavity defined by the inner surface 213, the lap joint 216, and the seal 208. Notably, FIG. 4 depicts the circuit 200 in an inflated condition.

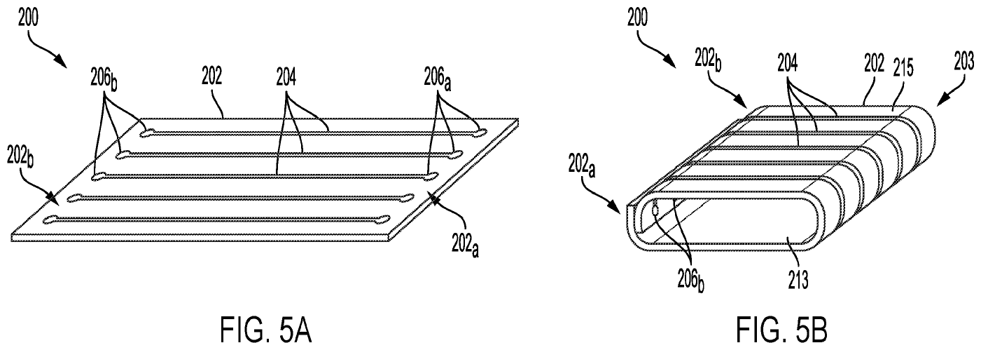

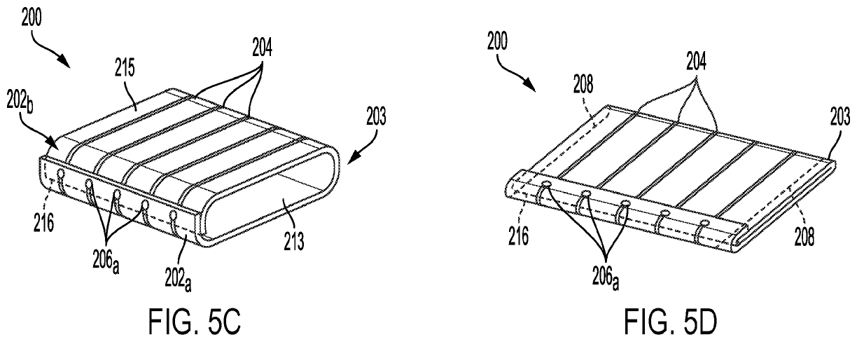

Referring now to FIGS. 5A-5E, several assembly diagrams of the fluid-fillable circuit 200 of FIG. 4 are depicted in accordance with at least one non-limiting aspect of the present disclosure. Specifically, FIG. 5A illustrates how the layup 202 can have a first portion 202ₐ and a second portion 202_{b}. A first plurality of vias 206ₐ can be positioned on the first portion 202ₐ and a second plurality of vias 206_{b} can be positioned on the second portion 202_{b}. Each trace 204 from the plurality of traces 204 can be electrically coupled to corresponding vias 206ₐ, 206_{b} and thus, configured to traverse the layup 202 from the first portion 202ₐ to the second portion 202_{b}.

In reference to FIG. 5B, a fold 203 in the layup 202 is illustrated such that the first portion 202ₐ of the layup 202 is aligned with the second portion 202_{b}. More specifically, the vias 206ₐ (not shown) of the first portion 202ₐ are aligned with the vias 206_{b} of the second portion 202_{b}. After alignment, the vias 206ₐ (not shown) of the first portion 202ₐ can be electrically coupled to the vias 206_{b} of the second portion 202_{b}. Moreover, the alignment of FIG. 5B prepares the layup 202 for the bonding procedure that will result in the lap joint 216. For example, the fold 203 in the layup 202 is particularly configured such that an inner surface 213 of the first portion 202ₐ of the layup 202 can mechanically engage an outer surface 215 of the second portion 202_{b} of the layup 202.

Accordingly, the layup 202 of FIG. 5B is properly aligned and prepared for the bonding process, as depicted in FIG. 5C. The first portion 202ₐ of the layup 202 can be bonded to the second portion 202_{b} of the layup 202 by any known process of attachment (e.g., welding, soldering, fusing, stitching, adhesives, etc.), thereby creating the lap joint 216. The process can further secure the electrical connection of the vias 206ₐ on the first portion 202ₐ of the layup 202 to the vias 206_{b} on the second portion 202_{b} of the layup 202. Since, each trace 204 is electrically coupled to corresponding vias 206ₐ, 206_{b}, when each pair of corresponding vias 206ₐ, 206_{b} are electrically coupled, that part of the circuit 200 (e.g., first via 206ₐ, second via 206_{b}, and the connecting trace 204) is closed and mechanically secured to ensure a robust electrical connection.

Referring now to FIG. 5D, after the lap joint 216 is formed, the circuit 200 can be flattened along the fold 203, such that a majority of the inner surface 213 of the layup 202 is faces, but is not adhered to another portion of the inner surface 213 of the layup 200. Accordingly, a seal 208 may be formed on either side of the circuit, wherein each seal 208 is perpendicular to the lap joint 216. The seals 208 can be formed by any known process of attachment (e.g., welding, soldering, fusing, stitching, adhesives, etc.) and this process can be done in conjunction with, or separate from, the creation of the lap joint 216. One or more notches can be introduced into the layup 202, prior to the formation of the seals 208, to reduce mechanical interference during inflation.

Accordingly, the fluid-fillable circuit 200 can be assembled such that a majority of the inner surface 213 of the layup 202 is folded such that it faces—but is not adhered to—another portion of the inner surface 213 of the layup 200 and thus, forms an internal cavity of the fluid-fillable circuit 200. A fluid can be inserted into the internal cavity formed by the inner surface 213, lap joint 216, and seals 208 of the layup 200 and contained. As more fluid is inserted within the internal cavity, the more pressure will be exerted on the inner surfaces 213 of the layup 202. Due to the deformable nature of the layup 202 and traces 202, the circuit 200 can be inflated, as illustrated in FIG. 5E.

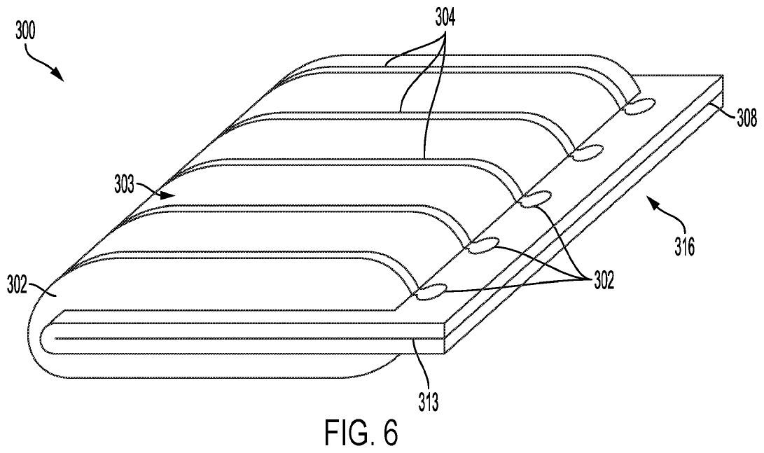

Referring now to FIG. 6, a perspective view of another inflatable circuit 300 is depicted in accordance with at least one non-limiting aspect of the present disclosure. Similar to the circuit 200 of FIG. 4, the circuit 300 of FIG. 6 can include a single layup 302 construction, wherein the single layup 302 can include a plurality of traces 304 and a plurality of vias 306. Once again, the single layup 302 of FIG. 6 can include a multi-layer construction, similar to the layups 102ₐ, 102_{b} of FIG. 2. Likewise, each trace 304 of the plurality can be constructed from a deformable conductive material deposited on or within a substrate layer and encapsulated. According to some non-limiting aspects, the layup 302 can further include a stencil layer, which can define paths for the traces 304 in which the deformable conductor can be deposited and contained.

Similar to the circuit 200 of FIG. 4, the layup 302 can be folded such that a first portion of the layup 302 interfaces with a corresponding, second portion of the layup 302. The layup 302 can be geometrically configured such that, when the layup 302 is folded or rolled, one or more vias 306 positioned on the first portion of the layup 302 can be aligned and placed in electrical communication with a corresponding via 306 the second portion of the layup 302. The alignment of the vias 306 may result in a desired alignment of traces 304 as shown in this embodiment, or traces may be misaligned or otherwise have an asymmetric configuration. As shown here, the vias traverse linearly and in alignment between a via 304 on the first portion and a via 304 on the second portion. However, according to the non-limiting aspect of FIG. 6, the circuit 300 can be folded or rolled such that every portion of an inner surface 313 of the layup 302 faces another portion of the inner surface 313 of the layup. In other words, no portion of the layup 302 of FIG. 6 overlaps with another portion and thus, the circuit 300 of FIG. 6 does not have a lap joint 216 (FIG. 4), such as the circuit 200 of FIG. 4. Rather, once the vias 306 and traces 304 are aligned, a seal 308 can be formed between inner surfaces 313 of the first and second portions of the layup 302 by any known process of attachment (e.g., welding, soldering, fusing, stitching, adhesives, etc.). In an alternative embodiment (not shown), the outer surface 315 may be folded or rolled over at a free edge of the layup 302, e.g., the edge comprising vias 306, such that the outer surfaces 315 contact one another, and the seal 308 formed adjacent this edge such that the seal 308 is contained within the cavity defined within the interior surface 313 of the layup 302. The remaining edges, e.g., the remaining two edges at opposite ends of the circuit 300, may be sealed as shown here. In another aspect (not shown), two free edges may be folded or rolled over such that the outer surfaces may contact one another, and the seal 308 formed adjacent these edges such that the seal is contained between the interior surface 313. The remaining edge(s), e.g., the remaining edges comprising the vias of the circuit 300, may be sealed as shown here. According to the non-limiting aspect where the single layup 302 has a construction similar to the layups 102ₐ, 102_{b} of FIG. 2, an encapsulation or substrate layer of the layup 302 can be overlaid onto itself such that vias 306 positioned on the first portion of the layer can be aligned with and electrically coupled to a corresponding via 306 positioned on the second portion of the encapsulation layer. The seal(s) 308 may comprise the overlaid vias, thereby providing reliable mechanical and electrical coupling of the vias to one another.

According to the non-limiting aspect of FIG. 6, the seal 308 can create an edge joint 316 that, along with the fold 303, can form an internal cavity similar to the internal cavity 110 of FIG. 2. Similar to the multi-layup circuit 100 of FIG. 2, when assembled, the internal cavity defined by the circuit 300 of FIG. 6 can accommodate and contain a fluid. Although the circuit 300 of FIG. 6 defines an internal cavity having a stadium-like cross section, the fluid-fillable circuit 300 can be alternately configured to have a number of different geometries, depending on user preference and/or intended application. For example, according to some non-limiting aspects, the fluid-fillable circuit 300 can be circular, hexagonal, rectangular, or triangular. Similar to the circuit 100 of FIG. 1, according to other non-limiting aspects, the circuit 300 of FIG. 6 is one of a tessellated plurality. Regardless of its particular geometric configuration, the circuit 300 of FIG. 6 can be inflated by inserting a fluid into the internal cavity defined by the inner surface 313, the edge joint 316, and the fold 303. Notably, FIG. 6 depicts the circuit 300 in an inflated condition. According to other non-limiting aspects, a butt joint can be utilized to seal the circuit 300 about a thickness of the layup 302, in lieu of the edge joint 316 of FIG. 6.

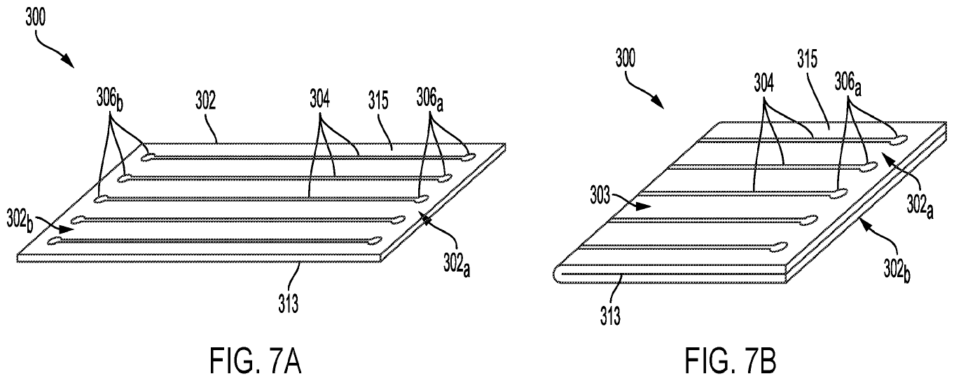

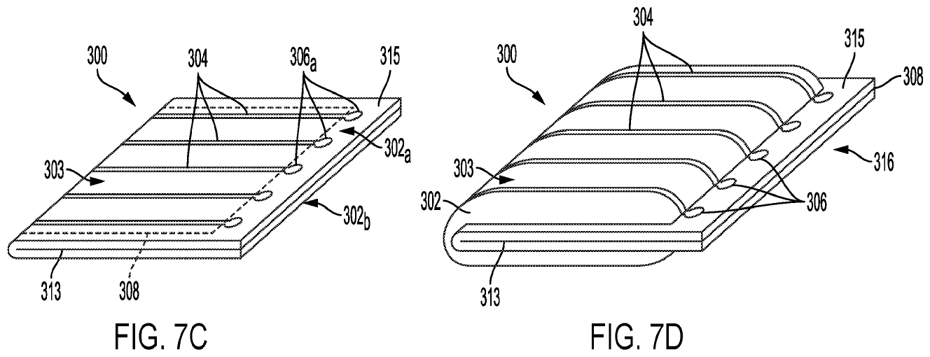

Referring now to FIGS. 7A-7D, an assembly of the fluid-fillable circuit 300 of FIG. 6 is depicted in accordance with at least one non-limiting aspect of the present disclosure. Specifically, FIG. 7A illustrates how the layup 302 can have a first portion 302ₐ and a second portion 302_{b}. A first plurality of vias 306ₐ can be positioned on the first portion 302ₐ and a second plurality of vias 306_{b} can be positioned on the second portion 302_{b}. Each trace 304 from the plurality of traces 304 can be electrically coupled to corresponding vias 306ₐ, 306_{b} and thus, configured to traverse the layup 302 from the first portion 302ₐ to the second portion 302_{b}.

In reference to FIG. 7B, a fold 303 in the layup 302 is illustrated such that the first portion 302ₐ of the layup 302 is aligned with the second portion 302_{b}. According to the non-limiting aspect of FIG. 7B, the circuit 300 can be folded such that the edges of the portions 302ₐ and 302_{b} are aligned. As shown in this aspect, the inner surface 313 of the first portion 302ₐ of the layup 302 faces the inner surface 313 of the second portion 302_{b} of the layup 302. The vias 306ₐ of the first portion 302ₐ of the layup 302 can be aligned with the vias 306_{b} (not shown) of the second portion 302_{b} of the layup 302. After alignment, the vias 306ₐ of the first portion 302ₐ can be electrically coupled to the vias 306_{b} (not shown) of the second portion 302_{b}. Moreover, the alignment of FIG. 7B prepares the layup 302 for the bonding procedure that will result in an edge joint 316.

Accordingly, the layup 302 of FIG. 7B is properly aligned and prepared for the bonding process, as depicted in FIG. 7C. A seal 308 can be formed between the first portion 302ₐ and the second portion 302_{b}, as shown here at the inner surface 313,by any known process of attachment or unitizing (e.g., welding, soldering, fusing, stitching, adhesives, etc.). The seal 308 of this embodiment creates an edge joint 316 between the first and second portions 302ₐ, 302_{b} that comprises the vias 306ₐ, 306_{b}. The process as shown may thus mechanically secure the electrical connection of the vias 306ₐ to the vias 306_{b}. Since each trace 304 is electrically coupled at corresponding vias 306ₐ, 306_{b}, when each pair of corresponding vias 306ₐ, 306_{b} are electrically coupled that part of the circuit 300 (e.g., first via 306ₐ, second via 306_{b}, and the connecting trace 304) is closed and mechanically secured to ensure a robust electrical connection. It should be appreciated that a seal may be provided in a portion (not shown) of the circuit 300 that does not contain vias, and optionally the seal may not be located at free edges of the circuit 300 thereby providing uninflated portions (not shown) that extend beyond the seal. The seal may comprise traces and thus, traces from an inflated portion may be in electrical communication with uninflated portions of the circuit 300. It may be appreciated that vias may be located in any permutation of inflated portions, seals or joints, or uninflated portions of the circuit 300. Vias that connect one trace end to another trace end may provide open or closed electrical communication in a single trace or between different traces of the circuit 300, to an electronic component, or to another inflated or uninflated circuit.

In further reference to FIG. 7C, after the edge joint 316 is formed, a substantial portion of the inner surface 313 of the layup 302 can face—but is not adhered to—another portion of the inner surface 313 of the layup 300. Accordingly, the seal 308, which can be formed on every side of the circuit 300 that is not bound by the fold 303, can form an internal cavity (e.g., similar to the internal cavity 110 of FIG. 2) of the fluid-fillable circuit 300. A fluid can be inserted into and contained by the internal cavity formed by the inner surface 313, edge joint 316, and fold 303. As more fluid is inserted within the internal cavity, the more pressure will be exerted on the inner surfaces 313 of the layup 302. Due to the deformable nature of the layup 302 and traces 304, the circuit 300 can be inflated, as illustrated in FIG. 7D.

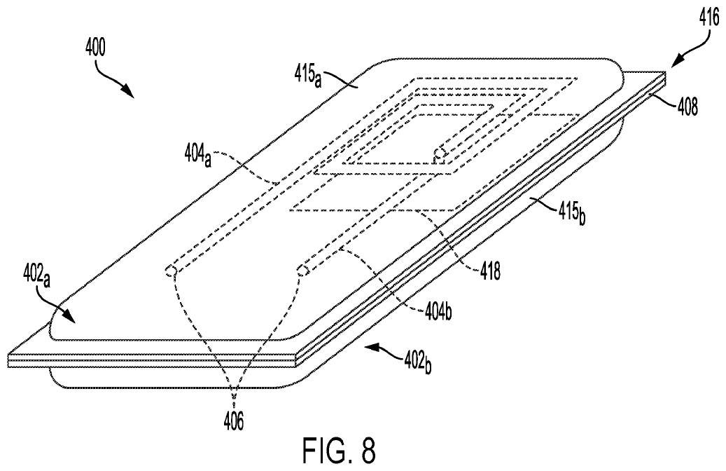

Referring now to FIG. 8, a perspective view of another inflatable circuit 400 is depicted in accordance with at least one non-limiting aspect of the present disclosure. According to the non-limiting aspect of FIG. 8, the traces 404ₐ, 404_{b} of the fluid-fillable circuit 400 can be particularly configured such that the fluid-fillable circuit can perform a variety of electrical functions. In other words, whereas the previously discussed aspects of FIGS. 1-7 described several non-limiting mechanical constructions and interconnects between traces of several inflatable circuit embodiments, the non-limiting aspect of FIG. 8 demonstrates a fluid-fillable circuit 400 electrically configured to perform an intended function, which can vary depending on the intended application. Specifically, an electrical current and/or potential can be applied to the circuit 400, e.g., at vias 406 and, when the circuit 400 is inflated, an electrical parameter may be generated (e.g., an inductance, a resistance, a voltage drop, a capacitance, signal, an electromagnetic field, etc.) that is associated with the trace pattern configuration and applied current and/or potential. According to some non-limiting aspects, electronic components (e.g., a power source, a microprocessor, a logic-based controller, etc.) can be mechanically secured to and/or otherwise integrated with the layups 402ₐ, 402_{b} and/or electrically coupled to the traces 404ₐ, 404_{b} of the circuit 400. The electronic components can be configured to receive and utilize signals from the traces 404ₐ, 404_{b} and electrical parameters from the traces 404ₐ, 404_{b} in accordance with the intended application. The electrical parameters and signals may vary with a physical change to the fluid-filled circuit 400, for example the inflation pressure, volume of the cavity, application of an external stimulus and/or deformation of the circuit 400. The resulting changes to the electrical parameters may be monitored, transmitted, or otherwise utilized to dynamically or statically calculate, infer or otherwise determine one or more physical or structural characteristics or conditions of the circuit 400, and/or stimuli applied to the circuit 400.

According to the non-limiting aspect of FIG. 8, the fluid-fillable circuit 400 can include a first layup 402ₐ and a second layup 402_{b}, which can be positioned, coupled, and sealed together in accordance with the fluid-fillable circuit 100 of FIG. 1. Specifically, the first layup 402ₐ can be coupled to the second layup 402_{b} via a seal 408 between inner surfaces (not shown) of the first and second layup 402ₐ, 402_{b}, thereby forming an edge joint 416 between the two layups 402ₐ, 402_{b}. The first layup 402ₐ, the second layup 402_{b}, the seal 408, and the edge joint 416 can collectively define an internal cavity of the fluid-fillable circuit 400, similar to the internal cavity 110 of FIG. 2. The internal cavity can be configured to accommodate and contain a fluid. However, it shall be appreciated that the present disclosure contemplates other aspects in which other joints may be used to couple the first and second layup 402ₐ, 402_{b}. According to other aspects, the fluid-fillable circuit 400 of FIG. 8 can be made from a single layup using the techniques described in reference to FIGS. 4 and 6 and the associated descriptions thereof. Substrate layers of the first layup 402ₐ and second layup 402_{b} can have an outer surface 415ₐ, 415_{b} on which one or more traces 404ₐ, 404_{b} made from a deformable conductor can be deposited and encapsulated.

In further reference to FIG. 8, the traces 404ₐ can form a multi-layer or multi-level coil in a layup, e.g., the layup 402ₐ. The coiled trace 404ₐ can have a depth, meaning the coils descend towards the substrate layer of the layup 402ₐ, in some embodiments forming an Escher-like staircase configuration. The coil may be constructed using the principles disclosed in U.S. Provisional Application No. 63/270,589, titled FLEXIBLE THREE-DIMENSIONAL ELECTRONIC COMPONENT, filed Oct. 22, 2021 the disclosure of which is hereby incorporated by reference in its entirety. The trace 404ₐ can be specifically configured to generate a desired electrical parameter when an electric current and/or voltage is applied to the circuit 400. For example, since the trace 404ₐ of FIG. 8 is arranged in a coiled configuration, a current may generate a particular inductive and/or electromagnetic response as it is applied to the circuit 400 and traverses the trace 404ₐ. For example, an electromagnetic field may be generated by a current applied to the coil. However, other electrical parameters, such as an electrical resistance and/or a voltage drop across the trace 404ₐ may be simultaneously or separately generated and/or monitored as a current and/or potential is applied to the circuit 400 and the current traverses the trace 404ₐ.

Still referring to FIG. 8, a conductive layer 418, may be provided such as the conductors described in U.S. patent application Ser. No. 17/192,725, titled DEFORMABLE INDUCTORS, filed Mar. 4, 2021 and/or PCT Patent Application No. PCT/US2021/071374, titled WEARABLE ARTICLE WITH FLEXIBLE INDUCTIVE PRESSURE SENSOR, filed Sep. 3, 2021, the disclosures of both which are hereby incorporated by reference in their entirety. The conductive layer 418 can be mechanically coupled to an outer surface 415, an inner surface, or laid up in between any of the layers of the second layup 402_{b}. The conductive layer 418 can be generally positioned opposite the inductive coil formed by the trace 404ₐ on or within the first layup 402ₐ and can define a surface area that correlates to or that is large enough to fully encompass, or bound, all of the coils formed by the trace 404ₐ. Collectively, the coiled trace 404ₐ and conductive layer 418 can function as an inductive sensor configured to utilize inductive responses generated by the coiled trace 404ₐ to determine a relative distance between the coiled trace 404ₐ on the first layup 402ₐ and the conductive layer 418 on the second layup 402_{b}. The conductive layer 418 can be alternately and/or additionally configured to serve other functions, such as those described in U.S. Provisional Patent Application No. 63/261,266, titled STRETCHABLE AND FLEXIBLE METAL FILM STRUCTURES, filed Sep. 21, 2021, the disclosure of which is hereby incorporated by reference in its entirety. For example, the conductive layer 418 can be configured to simultaneously serve as an electromagnetic shield. Likewise, the conductive layer 418 can be manufactured from a conductive film and configured for use as a high-power bus, as needed. In other non-limiting aspects, the coiled trace 404ₐ is positioned on the bottom layup 402_{b} and the conductive layer 418 is positioned on the top layup 402ₐ, as long as they are opposing each other and the conductive layer 418 is large enough to encompass all of the coils formed by the trace 404ₐ.

According to some non-limiting aspects, one or more electronic components (e.g., a microprocessor, a logic-based controller, etc.) can be coupled to the circuit 400 via a trace 404ₐ, 404_{b} positioned on one of the layups 402ₐ, 402_{b} Alternately and/or additionally, one or more electronic components can be coupled to one or more traces 406ₐ, 406_{b} of the layups 402ₐ, 402_{b}. The electronic component can be configured to receive and process signals from the coiled trace 404ₐ and/or the conductive layer 418. For example, the electronic component can be a microprocessor configured to correlate an inductive response generated by the coiled trace 404ₐ to relative distance between the coiled trace 404ₐ and the conductive layer 418, as will be further explained below. According to other non-limiting aspects, the electronic component can be a capacitor configured to create a resistor, an inductor, and a capacitor circuit configured to sense proximity of the coiled trace 404ₐ to the conductive layer 418.

Because the first layup 402ₐ, the second layup 402_{b}, and the traces 404ₐ, 404_{b} can be fabricated from flexible and/or deformable materials, the circuit 400 of FIG. 8 can stretch as a fluid is introduced to the internal cavity. In other words, the circuit 400 of FIG. 4 can be selectively inflated and deflated as the fluid is introduced and/or removed from the internal cavity. As the circuit 400 is inflated and deflated, one or more dimensions (e.g., length, cross-sectional area, etc.) of the traces 404ₐ will change. According to some non-limiting aspects, one or more dimensions of the electrical features (e.g., traces 404ₐ, 404_{b}) of the layups 402ₐ, 402_{b} can change between a fraction of a percent and about thirty percent as the circuit 400 transitions between an inflated and deflated condition. As the dimensions of the electrical features (e.g., traces 404ₐ, 404_{b}) change, one or more electrical parameters (e.g., an inductance, a resistance, a voltage drop, a capacitance, and an electromagnetic field, etc.) generated by the applied current as it traverses the circuit 400 will subsequently change. In other words, the electrical parameters of the circuit 400 will change as the circuit 400 is inflated and deflated, even though the applied current and/or voltage remains constant.

Although the deformation of the traces 404ₐ, 404_{b} discussed above a response to an internal pressure applied by the fluid onto the inner surfaces 413ₐ, 413_{b} of the layups 402ₐ, 402_{b}, it shall be appreciated that additional deformations may result from external pressures applied on the outer surfaces 415ₐ, 415_{b} of the layups 402ₐ, 402_{b}, which would cause further deformation of the layups 402ₐ, 402_{b} and traces 404ₐ, 404_{b}. According to some non-limiting aspects, a baseline deformation and a resulting electrical parameter can be established for an inflated condition of the circuit 400. Accordingly, any additional deformations and/or further differences in the generated electrical parameter due to those deformations can be compared to the baseline and utilized to characterize subsequent structural parameters associated with the circuit 400 associated with applied external pressures. This can be useful to monitor and characterize an environment in which the circuit 400 and/or the use of the circuit as an airbag, bladder, and/or cushion.

For example, according to the non-limiting aspect of FIG. 8, the coiled trace 404ₐ may generate a first inductive response when the circuit 400 is deflated and a second inductive response when the circuit 400 is inflated. The electrical parameter (e.g., strength of the inductive response) is a function of the distance between the coiled trace 404ₐ and the conductive layer 418. The conductive layer 418 can detect electrical parameters (e.g., inductance) generated by the coiled trace 404ₐ and can send signals associated with detected electrical parameters to one or more electronic components via one or more connecting traces 404ₐ, 404_{b} and/or one or more vias 406ₐ, 406_{b}. For example, the electronic components can include a microprocessor configured to determine a difference between detected electrical parameters and correlate the determined difference to a structural parameter (e.g., a strain, a stress, a pressure, a dimension, etc.) associated with the fluid-fillable circuit 400. According to some non-limiting aspects, the correlation can be based on a particular electrical parameter value or a particular range of electrical parameter values, which would provide the user with a margin of error in case an electrical parameter value is not exactly replicated each time the circuit expands and/or contracts. In other words, the fluid-fillable circuit 400 can be configured such that an electrical characterization of the fluid-fillable circuit 400 can be used to characterize a physical condition of the fluid-fillable circuit 400. This can be useful in applications where the fluid-fillable circuit 400 is a bladder, or airbag of sorts, and the user wants to monitor and adjust the inflation for use as an adjustable cushion.

According to the non-limiting aspect of FIG. 8, the coiled trace 404ₐ and conductive layer 418 of FIG. 4 can be implemented to determine, quantify and/or otherwise characterize a strain applied to the fluid-fillable circuit 400 by the fluid in the internal cavity. However, it shall be appreciated that the coiled configuration of the trace 4043 of FIG. 8 is merely presented for illustrative purposes. According to other non-limiting aspects, other sensors and/or sensing techniques can be implemented in lieu of either the coiled trace 404ₐ and/or the conductive layer 418 of FIG. 4. For example, radio-frequency identification (“RFID”) techniques, surface-acoustic-wave sensors (“SAW”), and/or hall-effect sensors can be implemented to achieve a similar result. According to other non-limiting aspects, the electrical parameter can include an electrical resistance generated by the current applied to the circuit 400. As the circuit 400 is inflated and deflated, a cross-sectional area and length of the traces 404ₐ, 404_{b} changes, resulting in a difference in electrical resistance through the circuit 400. This difference can be similarly correlated to a structural parameter (e.g., a strain, a stress, a pressure, a dimension, etc.) associated with the fluid-fillable circuit 400.

It shall be further appreciated that different geometries will be better suited for different applications, and that some geometries may be easier to manufacture. For example, the rectangular form of the coil defined by the trace 404ₐ on the first layup 402ₐ may be easier to manufacture than a curved-spiral trace 404ₐ and more conducive for lamination. Additionally, the relative dimensions of the coil formed by the trace 404ₐ and the conductive layer 418 can be selected in accordance with user preference and/or intended application. In some non-limiting aspects, the coiled trace 404ₐ can have a width and length no more than 20 to 30 millimeters, making the circuit 400 ideal for a seamless integration into a higher-level of assembly. Furthermore, the number of coils formed by the trace 404ₐ can be configured for a desired performance and can account for any constraints in any direction, such as a maximum depth of coil descent, which may relate to a total number of coil turns the laminate structure may accommodate. For example, the one-and-a-half coils formed by the trace 404ₐ of FIG. 8 was shown to generate an effective 75% gain in inductance for the same area as a single coil.

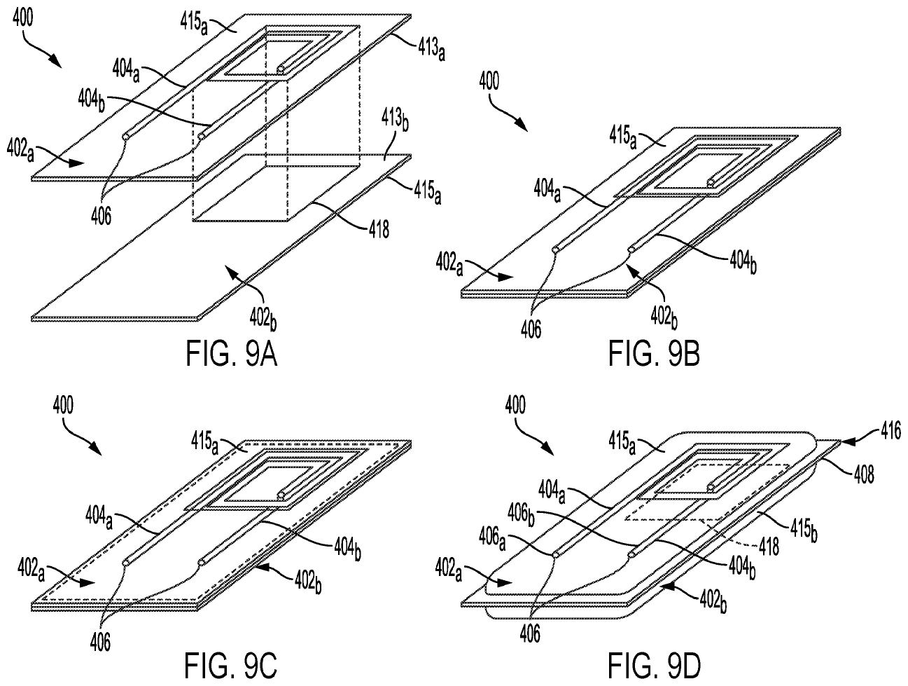

Referring now to FIGS. 9A-9D, an assembly of the fluid-fillable circuit 400 of FIG. 8 is depicted in accordance with at least one non-limiting aspect of the present disclosure. Specifically, FIG. 9A illustrates how the first layup 402ₐ can be aligned with the second layup 402_{b} such that the coiled trace 404ₐ aligns with the conductive layer 418. Moreover, the surface area of the conductive layer 418 is dimensioned such that the conductive layer 418 completely encompasses the coiled trace 404ₐ when the layups 402ₐ, 402_{b} are properly aligned.

In reference to FIG. 9B, a proper alignment of the first and second layups 402ₐ, 402_{b}—and more specifically, the coiled trace 404ₐ and conductive layer 418—is illustrated. After alignment, any corresponding electrical features on the first and second layups 402ₐ, 402_{b} can be electrically coupled. For example, an electronic component (or another fluid-fillable or non-fluid-fillable circuit containing an electronic component) may be coupled to one or more vias and/or contact points (as shown in FIG. 8) such that it is properly integrated with the circuit 400. Notably, according to the non-limiting aspect of FIG. 9, the coiled trace 404ₐ and conductive layer 418 are configured for inductive (e.g., electromagnetic) communication and thus, no electrical connection between the first and second layups 402ₐ, 402_{b} is necessary. The alignment of FIG. 9B prepares the layups 402ₐ, 402_{b} for the bonding procedure that will result in the edge joint 416.

Accordingly, the layups 402ₐ, 402_{b} of FIG. 9B are properly aligned and prepared for the bonding process, as depicted in FIG. 9C. A seal 908 can be formed between an inner surface 413ₐ of the first layup 402ₐ and an inner surface 413_{b} of the second layup 402_{b} by any known process of attachment (e.g., welding, soldering, fusing, stitching, adhesives, etc.). The seal 408 creates an edge joint 416 between the first and second layup 402ₐ, 402_{b}. In further reference of FIG. 9C, after the edge joint 416 is formed, a substantial portion of the inner surface 413ₐ of the first layup 402ₐ can face—but is not adhered to—a substantial portion of the inner surface 413_{b} of the second layup 402_{b}. Accordingly, the seal 408, which can be formed on every side of the circuit 400, can form an internal cavity (e.g., similar to the internal cavity 110 of FIG. 2) of the fluid-fillable circuit 400. A fluid can be inserted into and contained by the internal cavity formed by the inner surfaces 413ₐ, 413_{b}, the edge joint 416, and the seal 408. As more fluid is inserted within the internal cavity, the more pressure will be exerted on the inner surfaces 413ₐ, 413_{b} of the first and second layups 402ₐ, 402_{b}. Due to the deformable nature of the layups 402ₐ, 402_{b} and traces 404ₐ, 404_{b}, the circuit 400 can be inflated, as illustrated in FIG. 9D.

It shall be appreciated that while the foregoing embodiment has been described for a structure comprising two layups, any of the foregoing structures comprising a single layup and the associated description and methods of manufacture may be similarly applied to form a system similar to the system of FIGS. 8, 9A-D.

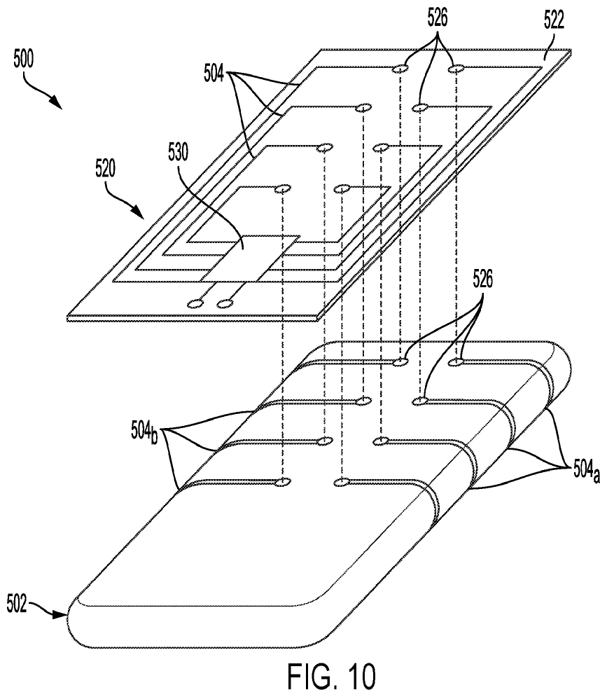

Referring now to FIG. 10, an assembly of another inflatable circuit 500 featuring an auxiliary device 520 is depicted in accordance with at least one non-limiting aspect of the present disclosure. According to the non-limiting aspect of FIG. 10, the fluid-fillable circuit 500 can include a plurality of traces 504ₐ, 504_{b} and vias 506, at least some of which are arranged such that they can be electrically coupled to an auxiliary device 520, such as an electronic component (e.g., a microprocessor, a logic-based controller, a battery, etc.) coupled to the fluid-fillable circuit 500. As such, the non-limiting aspect of FIG. 10 illustrates how a fluid-fillable circuit 500 can accommodate one or more auxiliary devices 520, which can supplement and/or enhance the electrical functionality described in reference to FIG. 8.

The fluid-fillable circuit 500 of FIG. 10 can include any of the constructions described in reference to FIGS. 1-9D. For example, according to the non-limiting aspect of FIG. 10, the circuit 500 has a single layup 502 construction. However, according to other non-limiting aspects, the fluid-fillable circuit 500 can have a multi-layup construction, such as the circuit 100 of FIG. 1. Regardless, the fluid-fillable circuit 500 of FIG. 10 defines an internal cavity via one or more joints and seals (not shown), such as the cavity 110 of FIG. 2. The internal cavity defined by the circuit 500 of FIG. 10 can accommodate and contain a fluid such that the circuit 500 can be inflated and/or deflated. However, the circuit 500 of FIG. 10 can include an alternate arrangement of traces 504ₐ, 504_{b} and vias 506 such that the circuit 500 is not complete until an auxiliary device 520 is electrically coupled to one or more via 506 of the plurality.

For example, according to the non-limiting aspect of FIG. 10, the circuit 500 can include one or more vias 506 in addition to vias positioned along a joint or seal, such as previously described vias 106 (FIG. 1), 206 (FIG. 4), 306 (FIG. 6). Notably, the vias 506 of FIG. 10 break the electrical continuity of one or more traces 504ₐ, 504_{b} positioned on the layup 502. The auxiliary device 520 can include its own electrical features positioned on its own substrate 522. According to some non-limiting aspects, the substrate 522 can be composed of the same material or have mechanical properties similar to those of the layup 502. For example, the substrate 522 can have a similar elastic modulus or other elastic properties to the layup 502, which can reduce the chances of a shear mismatch between the substrate 522 and layup 502 as the circuit 500 is inflated and/or deflated, which may result in delamination depending on the attachment, bonding or coupling method selected to attach the components to one another. Furthermore, one or more traces 524 and/or one or more vias 526 can be positioned on the substrate. According to some non-limiting aspects, the traces 524 of the auxiliary device 520 can be formed from the same deformable, conductive material or have mechanical properties similar to the material of the traces 504 of the layup 502. The vias 526 of the auxiliary device 520 can also be arranged and configured for mechanical and electrical engagement with corresponding vias 506 of the fluid-fillable circuit 500.

In further reference to FIG. 10, certain features (e.g., vias 526) of the auxiliary device 520 can be aligned with corresponding features (e.g., vias 506) of the fluid-fillable circuit 500. Once properly aligned, the auxiliary device 520 can be mechanically coupled to the layup 502 via any known process of attachment (e.g., welding, soldering, fusing, stitching, adhesives, etc.) and the vias 526 of the auxiliary device 520 can be electrically coupled to one or more of vias 506 of the layup 502. Accordingly, the traces 524 and vias 526 of the auxiliary device 520 can place a first side of a trace 504ₐ in electrical communication with a second side of the same trace 504_{b}. In other words, when the auxiliary device 520 is properly installed onto the fluid-fillable circuit 500 of FIG. 10, it completes the otherwise open circuit 500.

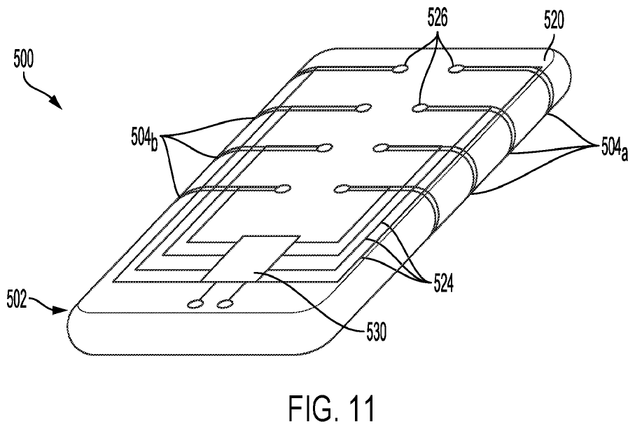

Referring now to FIG. 11, FIG. a perspective view of the assembled inflatable circuit 500 of FIG. 10 is depicted in accordance with at least one non-limiting aspect of the present disclosure. According to the non-limiting aspect of FIG. 11, the auxiliary device 520 can include one or more electronic components 530 (e.g., microprocessors, logic-based controllers, memories, transmitters, receivers, transceivers, sensors, power sources, resistors, capacitors, packages, signal converters, etc.) that are mechanically coupled to the substrate 522 and electrically coupled to the traces 526. It shall be appreciated that the electronic components 530 can be particularly selected and configured in accordance with an intended application of the fluid-fillable circuit 500. For example, according to some non-limiting aspects, the one or more electronic components 530 can include a microprocessor configured to receive a signal associated with an electrical parameter from one or more traces 504ₐ, 504_{b} of the layup 502. The microprocessor can be further configured to determine a difference between detected electrical parameters and subsequently correlate the determined difference to a structural parameter (e.g., a strain, a stress, a pressure, a dimension, etc.) associated with the fluid-fillable circuit 500.

According to some non-limiting aspects, the electronic components 530 can further include a memory configured to store instructions for the microprocessor and/or a lookup table. As such, the microprocessor can correlate the determined difference in electrical parameters to a structural parameter (e.g., a strain, a stress, a pressure, a dimension, etc.) associated with the fluid-fillable circuit 500 based, at least in part, on the lookup table stored in the memory. According to other non-limiting aspects, the one or more electronic components 530 can further include a transceiver configured to transmit signals received from the layup 502 and/or generated by the microprocessor for remote processing. The transceiver can be further configured to receive remotely-generated signals that include instructions for the microprocessor 530. According to other non-limiting aspects, the microprocessor 530 can be electrically coupled to a valve assembly in fluid communication with the internal cavity and can be configured to transmit commands to the valve assembly. As such, the valve assembly can insert and/or remove fluid to and from the internal cavity in accordance with a command received from the microprocessor 530.

According to other non-limiting aspects, the one or more electronic components 530 can include a logic-based circuit (e.g., a field-programmable gate array (“FPGA”), an application specific integrated circuit (“ASIC”), etc.) configured to perform a similar functions to the microprocessor, described above. In still other non-limiting aspects, the one or more electronic components 530 can include a power source configured to store a voltage, which can be provided to the traces 504ₐ, 504_{b} of the layup 504. According to some non-limiting aspects, the one or more electronic components 530 can include a sensor (e.g., a SAW sensor, a hall-effect sensor, an ultrasonic sensor, an optical sensor, etc.). According to other non-limiting aspects, the one or more electronic components 530 can include a System-on-a-Chp (“SoC”) that includes any of the above-referenced components and/or other components that are normally found in a standard computer system.

In further reference to FIG. 11, when the auxiliary device 520 is properly installed onto the fluid-fillable circuit 500, the auxiliary device 520—and more specifically, the one or more electronic components 530—can receive and transmit a current, voltage, and/or other signals from the traces 504ₐ, 504_{b}. Notably, the auxiliary device 520 can be adhered and/or bonded to the layup 502 either prior to inflation or after inflation, depending on use preference and/or intended application. According to other non-limiting aspects, the auxiliary device 520 can be manufactured via a lamination process such that it is integral, or unitized, to the layup 502. Regardless, when properly installed, the auxiliary device 520 can operate as a functioning component of the fluid-fillable circuit 500. Alternately and/or additionally, a fluid-fillable circuit 100 may be formed such that the circuit 100 is substantially flat in an uninflated configuration but can be molded to have varied three-dimensional surface topographies and shapes with varying degrees of complexity and contour. According to such aspects, three-dimensional forming can occur at the time of inflation, for example by a thermoforming with a mold cavity having the desired final three-dimensional shape using, for example, inflation pressure. According to other non-limiting aspects, a fluid-fillable circuit 100 or system may be similarly molded in a secondary operation post-inflation, for example by thermal compression-molding in a mold cavity having the desired final 3-dimensional shape. It shall be appreciated that such methods of formation can be employed to form any of the circuits disclosed herein.

According to some non-limiting aspects, an inductive proximity sensing configuration (e.g., the coiled trace 404ₐ and conductive layer 418 configuration of FIG. 8) can be implemented in conjunction with a strain sensing configuration (e.g., the elongating trace 504ₐ, 504_{b} configuration of FIG. 10). For example, a sensed strain can be correlated to a static internal pressure of the bladder, which can further be correlated to a spring rate for the system in which the bladder is installed, if used in a load bearing application. The sensed inductance can be correlated to a distance between features (e.g., the coiled layup 404ₐ, conductive layer 418) of the one or more layups, which can be further correlated to the spring rate to provide static or dynamic loads on a system in which the circuit is integrated.

Alternately and/or additionally, the circuit and/or electrically coupled electronic components (e.g., electronic component 530) can be configured to sense one or more of the aforementioned physical parameters associated with the circuit. For example, an inductive sensing configuration can be utilized to sense the static distance between a coil and a conductive layer, which can be used to determine an inflation pressure, a spring rate, a load, and/or other parameter associated with the circuit and/or one or more layups. A strain sensing configuration can be implemented to achieve a similar result.

Alternately and/or additionally, the circuits disclosed herein can be formed such that they can be positioned within a particular portion of an external housing, where the sensing of such parameters would be of particular interest. In other words, the circuits disclosed herein can be strategically positioned within an external housing such that the circuits are unconstrained and thus, capable of being filled with a fluid and/or inflated and sensing physical parameters in a location of interest. For example, a circuit can be formed in a fluid-fillable configuration disclosed herein, with one or more portions bonded to one or more relatively rigid structural components. However, according to such aspects, the strain sensor can be positioned away from the rigid structural components such that the bladder can experience larger deformations, and thus, can more easily sense and correlate electrical parameters associated with those deformations (e.g., force, strain rate, accelerations, loads, etc.).

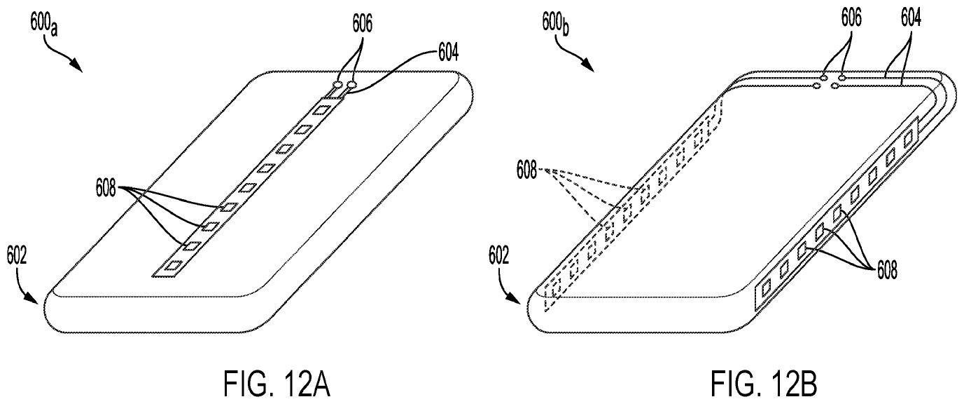

FIGS. 12A and 12B illustrate perspective views of other fluid-fillable circuits 600ₐ, 600_{b}, in accordance with at least one non-limiting aspect of the present disclosure. According to the non-limiting aspect of FIGS. 12A and 12B, each circuit 600ₐ, 600_{b} can be constructed from a single layup 602. However, according to other non-limiting aspects, either circuit 600ₐ, 600_{b} can have a multi-layup construction, such as the circuit 100 of FIG. 1. Regardless, the fluid-fillable circuit 600ₐ, 600_{b} of FIGS. 12A and 12B can define internal cavities via one or more joints and seals (not shown), such as the internal cavity 110 of FIG. 2. The internal cavity defined by the circuits 600ₐ, 600_{b} of FIGS. 12A and 12B can accommodate and contain a fluid such that the circuit 600 can be inflated and/or deflated. However, the circuit 600ₐ, 600_{b} of FIGS. 12A and 12B can include one or more light emitting diodes 608 (“LEDs”) mechanically coupled to or laminated within the layup 602 and optionally electrically coupled to one or more vias 606 by one or more traces 604. According to the non-limiting aspect of FIG. 12A, the circuit 600ₐ has LEDs 608 positioned on an upper surface of the layup 602. According to the non-limiting aspect of FIG. 12B, the circuit 600_{b} has LEDs 608 positioned on the sides of the layup 602. In both aspects, when a voltage is applied to the traces 604, the one or more LEDs 608 can be illuminated.

The one or more LEDs 608 can be implemented for cosmetic and/or functional purposes. For example, one or more of the LEDs 608 can be used in conjunction with an electronic component that includes an optical sensor, similar to the optical sensor discussed in reference to FIG. 11. As such, the optical sensor can be configured to detect photonic energy emitted by one or more of the LEDs 608, or light that was generated by one or more LEDs 608 and reflected off a surface of either inflatable circuit 600ₐ, 600_{b} and/or a surrounding structure. A microprocessor, similar to the microprocessor discussed in reference to FIG. 11, can be electrically coupled to, and configured to receive signals from, the optical sensor. The microprocessor can correlate signals received from the optical sensor to a structural parameter (e.g., a strain, a stress, a pressure, a dimension, etc.) associated with the fluid-fillable circuit 600ₐ, 600_{b}. According to another non-limiting aspect, the LEDs may be configured to illuminate in response to predetermined conditions measured, detected, calculated, inferred, correlated or sensed by a fluid-filled circuit system or assembly incorporating the principles described herein, for example with respect to FIGS. 1-11.

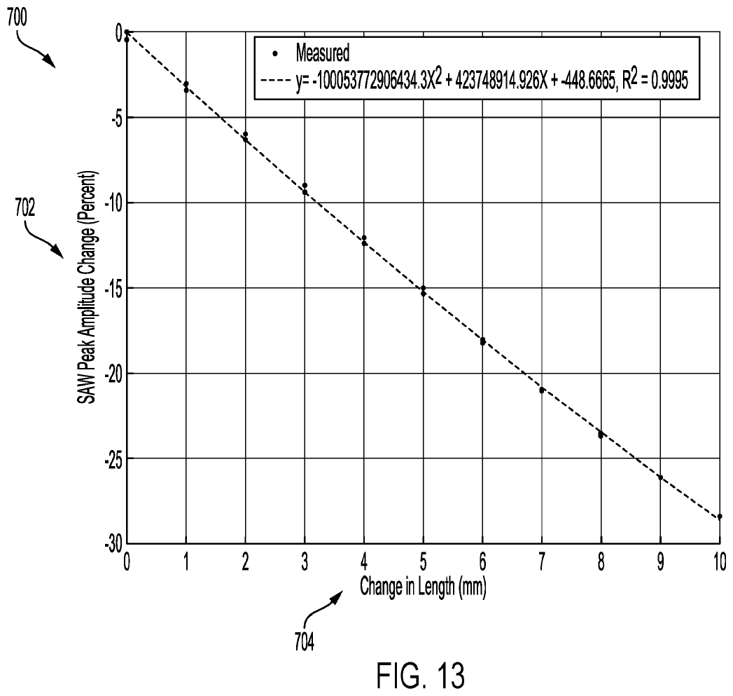

Referring now to FIG. 13, a chart 700 illustrating a correlation between an electrical parameter 702 and a structural parameter 704 of a fluid-fillable circuit is depicted in accordance with at least one non-limiting aspect of the present disclosure. According to the non-limiting aspect of FIG. 13, the fluid-fillable circuit can include an electronic component capable of sensing surface acoustic waves, such as the SAW antenna discussed in reference to FIG. 10. Accordingly, the electrical parameter 702 can include a peak amplitude of a surface acoustic wave detected by the SAW antenna. According to the non-limiting aspect of FIG. 13, the structural parameter 704 can include a dimension (e.g., length) of a trace of the fluid-fillable circuit.

According to the chart 700 of FIG. 13, as the circuit is inflated, the length of the trace increases due to the deformable composition of the length. In response to this increase in length, the electrical parameter 702, or peak amplitude of a surface acoustic wave generated by a current traversing the trace, decreases. The relationship between the electrical parameter 702 and structural parameter 704 can be mathematically characterized (e.g., via function, slope, etc.) such that a structural parameter 704 associated with the fluid-fillable circuit can be deduced based on the detected electrical parameter 702. Of course, similar models can be created for any electrical parameter in comparison to any structural parameter, in accordance with user preference and/or intended application.

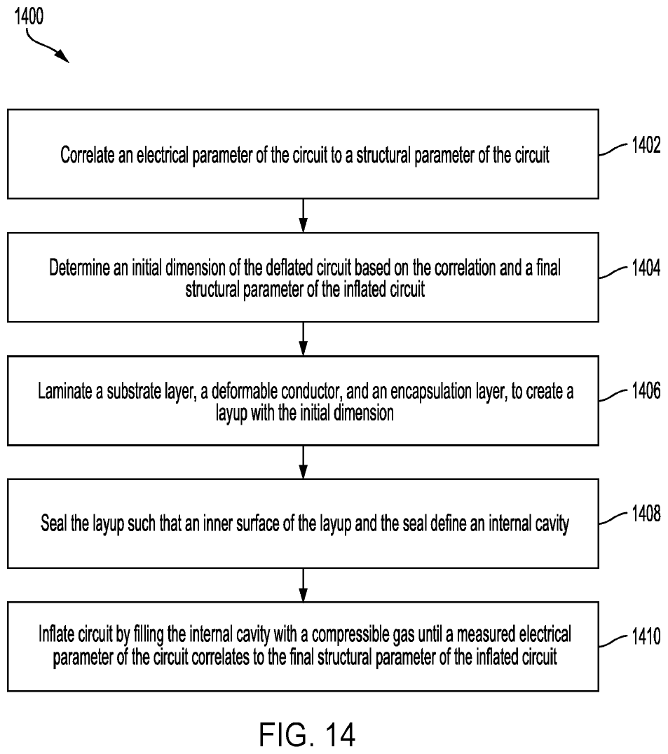

Referring now to FIG. 14, a flow chart illustrating a method 1400 of manufacturing a fluid-fillable circuit is depicted in accordance with at least one non-limiting aspect of the present disclosure. According to the non-limiting aspect of FIG. 14, the method 1400 can include correlating 1402 an electrical parameter (e.g., an inductance, a resistance, a voltage drop, a capacitance, and an electromagnetic field, etc.) of the circuit to a structural parameter (e.g., a dimension, a strain, a stress, a pressure, etc.) of the circuit. The method 1400 can further include determining 1404 an initial dimension of the deflated circuit based, at least in part, on the correlation and a final structural parameter of the inflated circuit. For example, if the circuit is to be inflated with a compressible fluid until a certain pressure is achieved within an internal cavity of the fluid-fillable circuit, a user may want to determine a final cross-sectional area or length of a trace, knowing that it will result in an electrical resistance or inductance that can be correlated with that particular pressure. The initial dimension of the trace, for example, can then be determined based on the final dimension. Once the initial dimension is determined, the method 1400 can include laminating 1406 at least a substrate layer, a deformable conductor, and an encapsulation layer, to create a layup that includes the initial dimension. Having created the layup, the method 1400 can further include sealing 1408 the layup such that an inner surface of the layup and the seal define an internal cavity, such as the internal cavity 110 of FIG. 2. Finally, the method 1400 can include inflating 1410 the circuit by filling the internal cavity with a compressible gas until a measured electrical parameter of the circuit correlates to the final structural parameter of the inflated circuit. In other words, the circuit can be inflated until a measured electrical parameter, such as resistance or inductance, correlates with the final structural parameter, such as the cross-sectional area or length. As such, a user can utilize the method 1400 of FIG. 4 to monitor electrical parameters across the circuit, to ensure the circuit is properly inflated to the correct pressure. This can be useful for benchmarking, calibration, and/or quality control, for example.

However, the steps illustrated in FIG. 14 are not the exclusive steps of the method 1400 contemplated by the present disclosure. For example, according to some non-limiting aspects, the method 1400 can further include depositing the deformable conductor within a patterned aperture of a stencil layer, thereby creating a trace of the fluid-fillable circuit assembly. According to such aspects, laminating the substrate layer, a deformable conductor, and an encapsulation layer, to create the layup can further include laminating the stencil layer. In other non-limiting aspects, the method 1400 can include laminating a second substrate layer, a second deformable conductor, and a second encapsulation layer, to create a second layup including the initial dimension, and sealing the layup to the second layup such that an inner surface of the layup, an inner surface of the second layup, and the seal define an internal cavity. Accordingly, the method 1400 can be employed to manufacture a multi-layup circuit, such as the circuit 100 of FIG. 1.

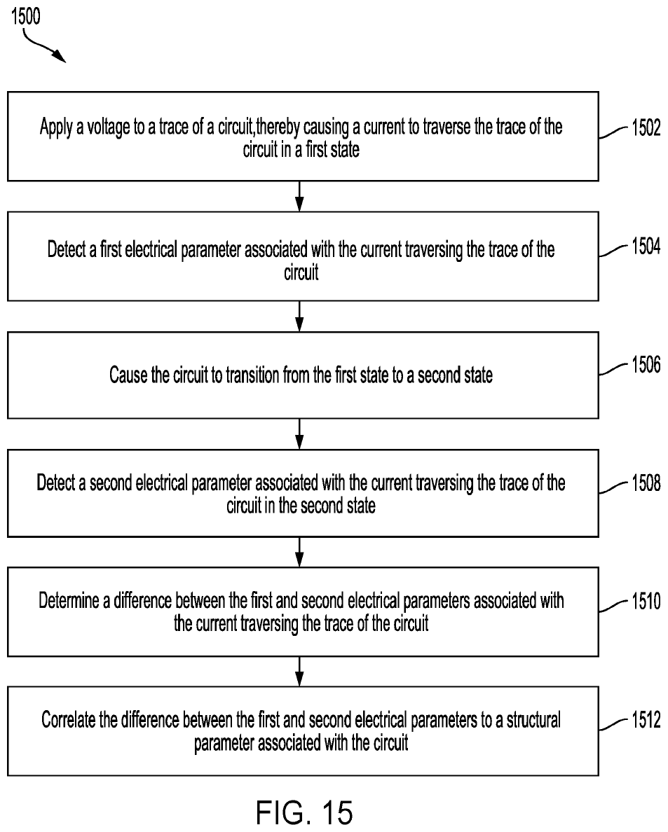

Referring now to FIG. 15, a flow chart illustrating a method 1500 of using a fluid-fillable circuit is depicted in accordance with at least one non-limiting aspect of the present disclosure. According to the non-limiting aspect of FIG. 15, the method 1500 can include applying 1502 a voltage to a trace of a fluid-fillable circuit in a first state, thereby causing a current to traverse the trace of the fluid-fillable circuit. Once a current is flowing through the circuit, the method 1500 can include detecting 1404 a first electrical parameter (e.g., an inductance, a resistance, a voltage drop, a capacitance, and an electromagnetic field, etc.) associated with the current traversing the trace of the fluid-fillable circuit in the first state. The method 1500 can further include causing 1506 the fluid-fillable circuit to transition from the first state to a second state. For example, causing 1506 the transition can include inserting a compressible fluid into an internal cavity defined by a layup of the fluid-fillable circuit. Alternately, causing 1506 the transition can include removing a compressible fluid from an internal cavity defined by a layup of the fluid-fillable circuit. According to other non-limiting aspects, causing 1506 the transition can include subjecting the fluid-fillable circuit to an external stimulus. The external stimulus can be physical (e.g., a load, an acceleration, a force, etc.), thermal (e.g., a temperature increase and/or decrease, etc.), and/or electromagnetic (e.g., an electrical load, a radio frequency, etc.) Upon inflation, the method 1500 can include detecting 108 a second electrical parameter associated with the current traversing the trace of the fluid-fillable circuit and determining 1510 a difference between the first and second electrical parameters associated with the current traversing the trace of the fluid-fillable circuit. Finally, the method can include correlating 1512 the difference between the first and second electrical parameters to a structural parameter (e.g., a strain, a stress, a pressure, a dimension, etc.) associated with the fluid-fillable circuit. Once again, the steps illustrated in FIG. 15 are not the exclusive steps of the method 1500 contemplated by the present disclosure.

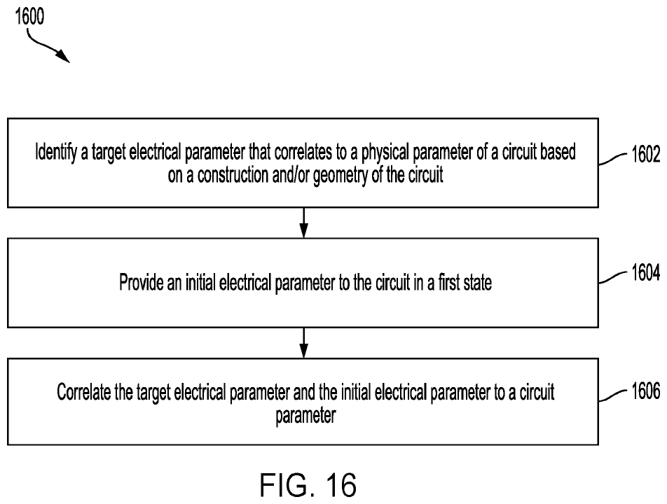

Referring now to FIG. 16, a flow chart illustrating another method 1600 of using a fluid-fillable circuit is depicted in accordance with at least one non-limiting aspect of the present disclosure. According to the non-limiting aspect of FIG. 16, the method 1600 can include identifying 1602 a target electrical parameter that correlates to a physical parameter of a circuit based on a construction and/or geometry of the circuit. For example, a target electrical parameter (e.g., resistance, inductance, etc.) can be identified for a given physical parameter (e.g., static inflation pressure, etc.) associated with the circuit based on its layup schedule and/or geometry. Next, based on this target, the method 1600 can include providing 1604 an initial electrical parameter to the circuit in a first state, such as when the circuit is not filled with a fluid. Finally, the method 1600 can include correlating 1606 the target electrical parameter and the initial electrical parameter to a circuit parameter (e.g., trace and/or trace pattern length, width, height, cross-sectional area, plan area, etc.). Once again, the steps illustrated in FIG. 15 are not the exclusive steps of the method 1500 contemplated by the present disclosure.

According to some non-limiting aspects, it may be preferable to compose the fluid-fillable circuits disclosed herein from alternate materials. For example, according to some non-limiting aspects, at least one layer of any of the layups described herein (e.g., first layup 102ₐ, second layup 102_{b}, etc.) can be composed of a silicone-based and/or rubber-like material, including thermoplastic polyurethanes, Silastic LC1000 silicone rubber, Momentive RTV-630 Blue, and/or polydimethylsiloxane (“PDMS”), amongst others. Such materials may provide mechanical or chemical properties that make them more suitable for some applications (e.g., high elongation or temperature resistance) and thus, may be particularly beneficial when implemented as a substrate layer and/or encapsulation layer for a layup when certain characteristics are needed for the final structure. In some examples, such properties could result in circuits that are more robust when washed repeatedly, which could be beneficial when the circuits disclosed herein are implemented via wearable devices. However, use of such materials may require alternate methods of manufacture. For example, whereas the previously disclosed materials may lend themselves to using pre-formed sheets in a lamination method of manufacture, a rubber-like material may utilize a casting, spraying, and/or molding-type method of manufacture. For example, it shall be appreciated that fluidic channels can be formed in a PDMS substrate using plasma activated bonding, as described by K. Choonee, R. R. A. Syms, M. M. Ahmad, and H. Zou in Post Processing of Microstructures by PDMS Spray Deposition, published in Volume 347 of the journal Sensors and Actuators A: Physical, which is scheduled to be published on Nov. 1, 2022.

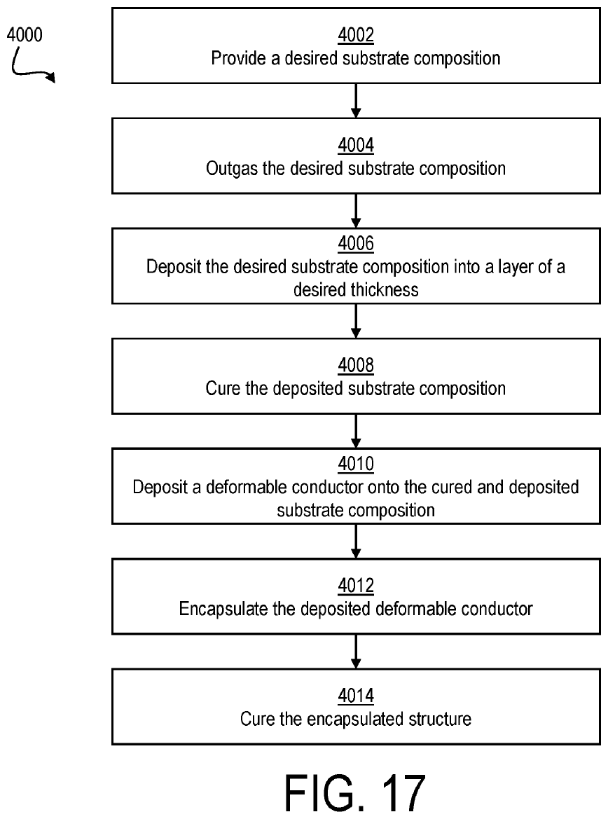

Referring now to FIG. 17, a flow chart of a method 4000 of manufacturing a substrate from which a fluid-fillable circuit can be produced is depicted in accordance with at least one non-limiting aspect of the present disclosure. Generally, the method 4000 of FIG. 17 can be used to produce at least one layer of at least one layup utilized in any of the fluid-fillable circuits disclosed herein from a silicone-based and/or rubber-like material. According to the non-limiting aspect of FIG. 17, the method 4000 can include providing 4002 a desired substrate composition. For example, the composition may require the provision and mixing of certain components. According to the non-limiting aspects wherein the substrate composition includes a Silastic LC1000 silicone rubber or a Momentive RTV-630 Blue, the substrate composition may require the provision of a Part A and a Part B, which need to be mixed according to the ratios specified in a corresponding data sheet to achieve the desired substrate composition. The method 4000 can further include outgassing 4004 the substrate composition. Since silicone-based and/or rubber-like materials can include a relatively high oil content compared to the alternate materials disclosed herein, such materials may require at least a minimum amount of outgassing. According to some non-limiting aspects, the outgassing 4004 can include a predetermined duration of exposure to a predetermined environment. For example, the predetermined environment can include a specified temperature range and, according to some non-limiting aspects, a vacuum. According to other non-limiting aspects, an oil-less (e.g., A-stage) PDMS may be used, within which most of the oils undergo a full reaction as the composition sets and thus, the oils are less likely to disperse within the uncured material as an impurity. Thus, the outgassing step 4004 can be optional, reduced, and/or omitted entirely, depending on the selected substrate composition.

In further reference to FIG. 17, the method 4000 can further include depositing 4006 the desired substrate composition into a layer of a desired thickness. According to the non-limiting aspect wherein the substrate composition includes a Silastic LC1000 silicone rubber, the deposition can include use of a screen-printing means to deposit the substrate composition onto a fabric such as Dyneema®, or any other suitable fabric. According to the non-limiting aspect wherein the substrate composition includes Momentive® RTV-630 Blue, the deposition can include pouring the substrate composition onto a flat surface and using a wiper blade, a roller, or other means until the substrate composition achieves a desired thickness. Upon achieving the desired thickness, the method 4000 can further include curing 4008 the deposited substrate composition and depositing 4010 a deformable conductor onto the substrate composition once it has cured. According to some non-limiting aspects, deposition of the deformable conductor can include a stencil layer. However, according to other non-limiting aspects, the deformable conductor can be deposited directly onto the substrate composition without the use of stencil layer as described in International Patent Application No. PCT/US2022/070853, titled DEVICES, SYSTEMS, AND METHODS FOR MAKING AND USING CIRCUIT ASSEMBLIES HAVING PATTERNS OF DEFORMABLE CONDUCTIVE MATERIAL FORMED THEREIN, and filed Feb. 25, 2022, the disclosure of which is herein incorporated by reference in its entirety. Finally, the method 4000 can include encapsulating 4012 the deposited deformable conductor. According to some non-limiting aspects, the encapsulation layer can include the same silicone-based and/or rubber-like material as the substrate composition. As such, the method 4000 can include curing 4014 the encapsulated structure. It shall be appreciated that unitization can occur as the substrate composition and encapsulation layers are cured. However, according to some non-limiting aspects, one or more layers or portions thereof may utilize one or more of a primer, catalyzer, plasma and/or corona discharge surface treatment to enhance and/or accelerate the unitization during the curing step 4012.

According to some non-limiting aspects, vias may be necessary to ensure multi-layer connectivity is established throughout the layup. However, use of a silicone-based and/or rubber-like material to compose the layup and the method 4000 of FIG. 17 could complicate the production of vias. Therefore, according to some non-limiting aspects, the method 4000 can further include the creation of vias using a material removal process such as a laser ablation or etching to remove the silicone-based and/or rubber-like material in a desired geometry and location of the via, and subsequently filling the resulting via with a deformable conductor to establish connectivity between various components of the circuit. For example, upon curing or unitization of an encapsulation or substrate layer, one or more vias can be laser-etched or milled, such deformable conductors deposited on additional layers may be in electrical communication with deformable conductors in other layers. Accordingly, silicone-based and/or rubber-like materials can be used to produce mutli-layer circuits, wherein the traces are routed vertically and horizontally when viewed in a cross-section.

Since the inventive principles of this patent disclosure can be modified in arrangement and detail without departing from the inventive concepts, such changes and modifications are considered to fall within the scope of the following claims. The use of terms such as first and second are for purposes of differentiating different components and do not necessarily imply the presence of more than one component.

Various aspects of the subject matter described herein are set out in the following numbered clauses:

Clause 1: A fluid-fillable circuit assembly, including a seal and a layup including a substrate layer, a deformable conductor, an encapsulation layer that covers the deformable conductor, and an inner surface, wherein the inner surface and the seal define an internal cavity of the fluid-fillable circuit assembly.

Clause 2: The fluid-fillable circuit assembly according to clause 1, wherein the layup further includes a stencil layer including a pattern of apertures, wherein the deformable conductor is contained within the pattern of apertures, and wherein the pattern of apertures defines at least one trace of the fluid-fillable circuit assembly.

Clause 3: The fluid-fillable circuit assembly according to clauses 1 or 2, further including an electronic componentlectrically coupled to the at least one trace of the fluid-fillable circuit assembly.

Clause 4: The fluid-fillable circuit assembly to any of clauses 1-3, wherein the layup is folded, wherein the seal traverses an unfolded side of the layup, and wherein the internal cavity is further defined by a fold in the layup.

Clause 5: The fluid-fillable circuit assembly according to any of clauses 1-4, wherein the seal includes an edge joint.

Clause 6: The fluid-fillable circuit assembly according to any of clauses 1-5, wherein the seal includes a lap joint that mechanically couples a portion of the inner surface to a portion of the outer surface, wherein the portion of the inner surface overlaps the portion of the outer surface.

Clause 7: The fluid-fillable circuit assembly according to any of clauses 1-6, wherein the seal further includes an edge joint that mechanically couples a third portion of the inner surface to a fourth portion of the inner surface.

Clause 8. The fluid-fillable circuit assembly according to any of clauses 1-7, further including a second layup including a second inner surface, wherein the internal cavity is further defined by the second inner surface, and wherein the seal mechanically couples the inner surface to the second inner surface.

Clause 9: The fluid-fillable circuit assembly according to any of clauses 1-8, wherein the seal includes an edge joint that mechanically couples a portion of the inner surface to a portion of the second inner surface.

Clause 10: The fluid-fillable circuit assembly according to any of clauses 1-9, wherein the inner surface includes at least one of a portion of the substrate layer and a portion the encapsulation layer.

Clause 11: The fluid-fillable circuit assembly according to any of clauses 1-10, wherein the internal cavity includes a volume that changes as the circuit assembly is inflated and deflated.

Clause 12: The fluid-fillable circuit assembly according to any of clauses 1-11, further including a compressible fluid within the internal cavity, wherein the compressible fluid exerts a pressure greater than an ambient pressure on the inner surface of the layup.

Clause 13: A fluid-fillable circuit assembly, including a seal, a first layup, and a second layup, wherein each of the first layup and the second layup includes a substrate layer, a deformable conductor, an encapsulation layer that covers the deformable conductor, and an inner surface, wherein the inner surface of the first layup, the inner surface of the second layup, and the seal define an internal cavity of the fluid-fillable circuit assembly.

Clause 14: The fluid-fillable circuit assembly according to either of clauses 12 and 13, wherein the seal includes an edge joint that mechanically couples a portion of the inner surface of the first layup to a portion of the inner surface of the second layup.

Clause 15: The fluid-fillable circuit assembly according to any of clauses 12-14, wherein each of the first layup and the second layup further include a stencil layer including a pattern of apertures, wherein the deformable conductor is contained within the pattern of apertures, and wherein the pattern of apertures defines at least one trace.

Clause 16: The fluid-fillable circuit assembly according to any of clauses 12-15, further including a via that electrically couples the at least one trace of the first layup to the at least one trace of the second layup.

Clause 17: The fluid-fillable circuit assembly according to any of clauses 12-16, further including a second via and a microprocessor, wherein the second via electrically couples microprocessor to the at least one trace of the fluid-fillable circuit assembly.

Clause 18: A method of manufacturing a fluid-fillable circuit assembly, the method including: correlating an electrical parameter of the circuit to a structural parameter of the circuit; determining an initial dimension of the deflated circuit based, at least in part, on the correlation and a final structural parameter of the inflated circuit; laminating a substrate layer, a deformable conductor, and an encapsulation layer, to create a layup including the initial dimension; sealing the layup such that an inner surface of the layup and the seal define an internal cavity; and inflating circuit by filling the internal cavity with a compressible fluid until a measured electrical parameter of the circuit correlates to the final structural parameter of the inflated circuit.

Clause 19: The method according to clause 18, wherein the motor includes a rotor, further including: depositing the deformable conductor within a patterned aperture of a stencil layer, thereby creating a trace of the fluid-fillable circuit assembly, and wherein laminating the substrate layer, a deformable conductor, and an encapsulation layer, to create the layup further includes laminating the stencil layer.

Clause 20: The method according to either of clauses 18 or 19, further including: laminating a second substrate layer, a second deformable conductor, and a second encapsulation layer, to create a second layup including the initial dimension; and sealing the layup to the second layup such that an inner surface of the layup, an inner surface of the second layup, and the seal define an internal cavity.

Clause 21: The method according to any of clauses 18-20, wherein inflating the circuit includes filling the internal cavity with a fluid.

Clause 22: The method according to any of clauses 18-21, wherein the fluid is compressible.

Clause 23: The method according to any of clauses 18-22, wherein the fluid is a gas.

Clause 24: A method of manufacturing a fluid-fillable circuit assembly, the method including: determining a target inflation amount for the fluid-fillable circuit assembly; determining a target electrical parameter value of the circuit that correlates to a structural parameter of the circuit; determining at least one initial structural parameter value for the fluid-filled circuit, the initial structural parameter value yielding an initial electrical parameter value; laminating a substrate layer, a deformable conductor, and an encapsulation layer, to create a layup including the at least one initial structural parameter value; sealing the layup such that an inner surface of the layup and the seal define an internal cavity; and inflating the circuit to the target inflation amount, wherein the target electrical parameter value is obtained at a target inflation pressure and the target electrical parameter value is different from the initial electrical parameter value.

Clause 25: The method according to clause 24, wherein the initial structural parameter value includes a trace length.

Clause 26: The method according to either of clauses 24 or 25, wherein the initial structural parameter value includes a trace width.

Clause 27: The method according to any of clauses 24-26, wherein the initial structural parameter value includes a trace cross-sectional area.

Clause 28: The method according to any of clauses 24-27, wherein the initial structural parameter value includes a plan area of a pattern of traces.

Clause 29: The method according to any of clauses 24-28, wherein the initial structural parameter value includes at least one from the group consisting of a trace length, a trace width, a trace cross-sectional area, and a plan area of a pattern of traces.

Clause 30: The method according to any of clauses 24-29, wherein the target electrical parameter value includes a resistance.

Clause 31: The method according to any of clauses 24-30, wherein the target electrical parameter value includes at least one from the group consisting of a magnetic field, a magnetic flux, an inductance, a voltage, a current, and a resistance.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

A highly sustainable inflatable laminate circuit structure may include a non-toxic and readily reclaimable deformable conductive material in combination with at least one layer of a readily recyclable material. The conductive material may form a pattern of traces and/or contact points on or encapsulated within the at least one layer. The method of forming the traces layer may include as few as one operation, produces substantially no waste (toxic or otherwise), and consumes no additional natural resources apart from those that constitute the layup materials. The method consumes substantially less energy compared to methods used to produce conventional circuit boards. The resulting circuits may be configured to form chambers or bladders that may be inflated, resulting in compressible fluid containment structures having integral, flexible and stretchable functional electronics.

A highly sustainable inflatable circuit assembly may include at least one laminate structure having at least one trace arranged in a pattern. The traces may have one or more terminals which may have one or more contact points or vias for interconnecting the pattern of traces to other electric structures. The laminate structure enables electric connections without the need for soldering, eliminates the need for substantial energy consumption, produces substantially no waste to manufacture, and emits substantially no volatile organic compounds (VOC's) during manufacturing.

A highly sustainable inflatable circuit assembly may include at least one electric component having terminals arranged in a pattern corresponding to a pattern of contact points of a laminate circuit structure. The electric component may have one or more terminals contacting one or more contact points. The electric component may be assembled to the laminate using a method that provides a reliable electrical connection without the need for soldering, eliminates the need for substantial energy consumption, produces substantially no waste, and emits substantially no volatile organic compounds (VOC's).

A highly sustainable and inflatable laminate circuit structure may include a layup formed from at least one stack of layers including at least one substrate layer, one or more stencil layers, and one or more insulation layers. One or more of the layers in the stack may be formed from a readily recyclable material. The stack of layers may include at least one pattern of traces and/or contact points and/or vias formed from a non-toxic and readily reclaimable conductive material. The pattern of conductive traces may be interconnected with the pattern of contact points and/or vias. A first pattern of traces, vias, and contact points may be formed on or recessed into a surface of the substrate layer. One or more stencil layers may be supported by the substrate layer with a second pattern of traces and/or contact points and/or vias extending through the entire thickness of the stencil layer. At least a portion of the stencil layer pattern may correspond to the substrate layer pattern. At least one insulation layer may be supported by the substrate and/or at least one stencil layer. The insulation layer may and have a pattern of contact points and/or vias on or extending through a surface of the insulation layer. At least a portion of the insulation layer pattern may correspond the substrate and/or stencil layer pattern. The conductive material may be deposited to one or more layers of the stack in a single operation that produces substantially no waste (toxic or otherwise), consumes no additional natural resources apart from those that constitute the layup materials, uses comparatively little energy, and emits substantially no VOC's. The various layers may be joined together to form the stack. The circuit layup may include multiple stacks, and two or more stacks may be joined together. Vias and contact points from one stack may be in communication with vias and contact points from another stack thereby providing communication between the stacks. Vias may extend through combinations of one or more of the substrate, stencil and insulation layers of each stack to provide communication between the traces of the stacks. Optionally, one or more layups may be configured such that at least two surfaces are opposing one another and have at least one portion that is not attached together. A sealed perimeter may be provided, and the layup may be inflated to form at least one chamber or bladder.

A highly sustainable inflatable laminate circuit structure or circuit assembly as described above may optionally include an encapsulant covering at least a portion of an electric component, vias, and/or contact points. The encapsulant may be formed from a readily recyclable material that may be like or the same as one or more of the layers of a layup or stack.

The substrate, stencil, and insulation layers may include a flexible material. The layers may include a stretchable material. At least a portion of one of the layers may have an adhesive property. The layers may be joined together by the adhesive property. The layers may be unitized in a unitizing operation. The laminate circuit structure may form an internal cavity that may be inflated.

A cavity may be formed from at least one laminate circuit structure having at least two stacked layups that have mating surfaces that, at least in some regions, are not bonded or otherwise attached to one another, but that have at least a perimeter shape where the mating surfaces are either attached, bonded, or integrally connected. The cavity may be inflated using known inflation methods.

The at least one electric device or component may be attached to the circuit structure after inflation, or prior to inflation. The electric device may include a surface mount component and/or an integrated circuit in a package. The at least one electric device may include a bare integrated circuit die. The at least one electric component may be attached to the circuit layup by the adhesive property of one of the layers, or may be attached to one of the layers by an adhesive.

The at least one electric component may be attached to an insulation layer or a substrate layer. The layers may have an adhesive property sufficient to reliably attach the electric component to the circuit layup. The conductive material may be deformable and have an adhesion characteristic that provides a reliable electrical connection between at least one contact point of the circuit layup and at least one terminal of the electric component without the need for soldering and eliminating the need for substantial energy consumption, producing substantially no waste, and emitting substantially no volatile organic compounds (VOC's).

A method of forming a layup or laminate circuit structure may include providing a substrate layer, forming one or more passages in the substrate layer, depositing a deformable conductive material in at least one of the passages, and stacking an insulation layer on the substrate layer, wherein the insulation layer at least partially encloses the deformable conductive material. Depositing the deformable conductive material in at least one of the passages may include wiping a volume of the conductive material over the at least one passage removing excess deformable conductive material from the surrounding substrate surface. Optionally, one or more may layups may be configured such that at least two surfaces are opposing one another and have at least one portion that is not attached together. A sealed perimeter may be provided, and the layup may be inflated to form at least one chamber or bladder.

A method of forming a layup or laminate circuit structure may include providing a substrate layer, and optionally forming one or more passages in a substrate layer and depositing a deformable conductive material in at least one of the substrate layer passages, sequentially stacking at least one stencil layer having one or more passages over the substrate layer, after stacking each stencil layer depositing the deformable conductive material in at least one of that stencil layer's passages, and stacking an insulation layer on the last-stacked stencil layer. At least one of the passages in each stencil layer may pass through the entire thickness of that layer. Successively stacked stencil layers may at least partially enclose the deformable conductive material of each a preceding layer. The insulation layer at least partially encloses the deformable conductive material in the at least one passage of the last-stacked stencil layer. Depositing the deformable conductive material may include wiping a volume of the conductive material over at least one passage removing excess deformable conductive material from the surrounding surface of the layer in which the passage is formed. Optionally, one or more layups may be configured such that at least two surfaces are opposing one another and have at least one portion that is not attached together. A sealed perimeter may be provided, and the layup may be inflated to form at least one chamber or bladder.

The substrate surface and at least one stencil layer surfaces may include a release layer. Release layers may be removed after deformable conductive material is deposited on the respective surface layers.

At least one of the passages in the substrate layer or at least one stencil layers may communicate with the at least one passages of another layer. Passages in stencil layers may pass through the layer's entire thickness.

A method may include forming at least one contact point on a circuit layup, the contact point including a deformable conductive material with an adhesion characteristic, and supporting an electric component on the circuit layup, the electric component having at least one terminal, wherein at least one terminal of the electric component contacts at least one of the contact points to form at least one electrical connection between the electric component and the contact point. The at least one terminal may include multiple terminals arranged in a pattern, the at least one contact point may include multiple contact points including the deformable conductive material and arranged in a pattern corresponding to the pattern of terminals of the electric component, and the multiple terminals of the electric component may contact the multiple contact points, wherein the adhesion characteristic of the deformable conductor provides a reliable electrical connection between the electric component and the contact points. Optionally, one or more layups may be configured such that at least two surfaces are opposing one another and have at least one portion that is not attached together. A sealed perimeter may be provided, and the layup may be inflated to form at least one chamber or bladder.

A method may include heating an inflated or non-inflated circuit assembly to a melting temperature of an encapsulation material, extracting electric components, heating the circuit assembly to the melting temperature one or more of a substrate, stencil and insulation layers, separating a conductive material from the circuit assembly, and purifying the conductive material. The method may further include the steps of re-using the electric components, reprocessing the layer material(s) and the conductive material for re-use.

A method for making a circuit layup may include providing a substrate layer, forming one or more passages in the substrate layer, collecting scrap material generated from the substrate layer providing and passage formation steps, depositing a deformable conductive material in at least one of the passages, providing an insulation layer and stacking the insulation layer on the substrate layer, collecting scrap material generated from the insulation layer providing steps, wherein depositing the deformable conductive material in at least one of the passages may include wiping a volume of the conductive material over the at least one passage removing excess deformable conductive material from the surrounding substrate surface, the insulation layer at least partially encloses the deformable conductive material, and the substrate and insulation layer scrap is reprocessed and the excess conductive material is included in making one or more subsequent circuit layups. Optionally, one or more layups may be configured such that at least two surfaces are opposing one another and have at least one portion that is not attached together. A sealed perimeter may be provided, and the layup may be inflated to form at least one chamber or bladder.

The present invention has been described with reference to various exemplary and illustrative aspects. The aspects described herein are understood as providing illustrative features of varying detail of various aspects of the disclosed invention; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed invention. Accordingly, it will be recognized by persons having ordinary skill in the art that various substitutions, modifications or combinations of any of the exemplary aspects may be made without departing from the scope of the invention. In addition, persons skilled in the art will recognize, or be able to ascertain using no more than routine experimentation, many equivalents to the various aspects of the invention described herein upon review of this specification. Thus, the invention is not limited by the description of the various aspects, but rather by the claims.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

As used herein, the singular form of “a”, “an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

Instructions used to program logic to perform various disclosed aspects can be stored within a memory in the system, such as dynamic random access memory (DRAM), cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, compact disc, read-only memory (CD-ROMs), and magneto-optical disks, read-only memory (ROMs), random access memory (RAM), erasable programmable read-only memory (EPROM), electrically erasable programmable read-only memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the non-transitory computer-readable medium includes any type of tangible machine-readable medium suitable for storing or transmitting electronic instructions or information in a form readable by a machine (e.g., a computer).

As used in any aspect herein, any reference to a processor or microprocessor can be substituted for any “control circuit,” which may refer to, for example, hardwired circuitry, programmable circuitry (e.g., a computer processor including one or more individual instruction processing cores, processing unit, processor, microcontroller, microcontroller unit, controller, digital signal processor (DSP), programmable logic device (PLD), programmable logic array (PLA), or field programmable gate array (FPGA)), state machine circuitry, firmware that stores instructions executed by programmable circuitry, and any combination thereof. The control circuit may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Accordingly, as used herein “control circuit” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

As used in any aspect herein, the term “logic” may refer to an app, software, firmware and/or circuitry configured to perform any of the aforementioned operations. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in memory devices.

As used in any aspect herein, the terms “component,” “system,” “module” and the like can refer to a computer-related entity, either hardware, a combination of hardware and software, software, or software in execution.

Unless specifically stated otherwise as apparent from the foregoing disclosure, it is appreciated that, throughout the foregoing disclosure, discussions using terms such as “processing,” “computing,” “calculating,” “determining,” “displaying,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

One or more components may be referred to herein as “configured to,” “configurable to,” “operable/operative to,” “adapted/adaptable,” “able to,” “conformable/conformed to,” etc. Those skilled in the art will recognize that “configured to” can generally encompass active-state components and/or inactive-state components and/or standby-state components, unless context requires otherwise.

1. A fluid-fillable circuit assembly, comprising a seal and a layup comprising a substrate layer, a deformable conductor, an encapsulation layer that covers the deformable conductor, and an inner surface, wherein the inner surface and the seal define an internal cavity of the fluid-fillable circuit assembly.

2. The fluid-fillable circuit assembly of claim 1, wherein the layup further comprises a stencil layer comprising a pattern of apertures, wherein the deformable conductor is contained within the pattern of apertures, and wherein the pattern of apertures defines at least one trace of the fluid-fillable circuit assembly.

3. The fluid-fillable circuit assembly of claim 2, further comprising an electronic component electrically coupled to the at least one trace of the fluid-fillable circuit assembly.

4. The fluid-fillable circuit assembly of claim 1, wherein the layup is folded, wherein the seal traverses an unfolded side of the layup, and wherein the internal cavity is further defined by a fold in the layup.

5. The circuit assembly of claim 4, wherein the seal comprises an edge joint.

6. The fluid-fillable circuit assembly of claim 5, wherein the seal comprises a lap joint that mechanically couples a portion of the inner surface to a portion of the outer surface, wherein the portion of the inner surface overlaps the portion of the outer surface.

7. The fluid-fillable circuit assembly of claim 6, wherein the seal further comprises an edge joint that mechanically couples a third portion of the inner surface to a fourth portion of the inner surface.

8. The fluid-fillable circuit assembly of claim 1, further comprising a second layup comprising a second inner surface, wherein the internal cavity is further defined by the second inner surface, and wherein the seal mechanically couples the inner surface to the second inner surface.

9. The fluid-fillable circuit assembly of claim 8, wherein the seal comprises an edge joint that mechanically couples a portion of the inner surface to a portion of the second inner surface.

10. The fluid-fillable circuit assembly of claim 1, wherein the inner surface comprises at least one of a portion of the substrate layer and a portion the encapsulation layer.

11. The fluid-fillable circuit assembly of claim 1, wherein the internal cavity comprises a volume that changes as the circuit assembly is inflated and deflated.

12. The fluid-fillable circuit assembly of claim 1, further comprising a compressible fluid within the internal cavity, wherein the compressible fluid exerts a pressure greater than an ambient pressure on the inner surface of the layup.

13. A fluid-fillable circuit assembly, comprising a seal, a first layup, and a second layup, wherein each of the first layup and the second layup comprises a substrate layer, a deformable conductor, an encapsulation layer that covers the deformable conductor, and an inner surface, wherein the inner surface of the first layup, the inner surface of the second layup, and the seal define an internal cavity of the fluid-fillable circuit assembly.

14. The fluid-fillable circuit assembly of claim 13, wherein the seal comprises an edge joint that mechanically couples a portion of the inner surface of the first layup to a portion of the inner surface of the second layup.

15. The fluid-fillable circuit assembly of claim 13, wherein each of the first layup and the second layup further comprise a stencil layer comprising a pattern of apertures, wherein the deformable conductor is contained within the pattern of apertures, and wherein the pattern of apertures defines at least one trace.

16. The fluid-fillable circuit assembly of claim 15, further comprising a via that electrically couples the at least one trace of the first layup to the at least one trace of the second layup.

17. The fluid-fillable circuit assembly of claim 16, further comprising a second via and an electronic component, wherein the second via electrically couples the electronic component to the at least one trace of the fluid-fillable circuit assembly.

18. A method of manufacturing a fluid-fillable circuit assembly, the method comprising:
correlating an electrical parameter of the circuit to a structural parameter of the circuit;
determining an initial dimension of the deflated circuit based, at least in part, on the correlation and a final structural parameter of the inflated circuit;
laminating a substrate layer, a deformable conductor, and an encapsulation layer, to create a layup comprising the initial dimension;
sealing the layup such that an inner surface of the layup and the seal define an internal cavity; and
inflating the circuit until a measured electrical parameter of the circuit correlates to the final structural parameter of the inflated circuit.

19. The method of manufacturing a fluid-fillable circuit assembly of claim 18, further comprising:
depositing the deformable conductor within a patterned aperture of a stencil layer, thereby creating a trace of the fluid-fillable circuit assembly, and wherein laminating the substrate layer, a deformable conductor, and an encapsulation layer, to create the layup further comprises laminating the stencil layer.

20. The method of manufacturing a fluid-fillable circuit assembly of claim 18, further comprising:
laminating a second substrate layer, a second deformable conductor, and a second encapsulation layer, to create a second layup comprising the initial dimension; and
sealing the layup to the second layup such that an inner surface of the layup, an inner surface of the second layup, and the seal define an internal cavity.

21-31. (canceled)
